(19) United States
(12) Patent Application Publication
(10) Pub. No.: US 2026/0059875 A1
(43) Pub. Date: Feb. 26, 2026

(54) PHOTODETECTION DEVICE

(71) Applicant: SONY SEMICONDUCTOR SOLUTIONS CORPORATION, KANAGAWA (JP)

(72) Inventors: RYOICHI NAKAMURA, KANAGAWA (JP); HIDENOBU TSUGAWA, KANAGAWA (JP)

(21) Appl. No.: 19/103,069

(22) PCT Filed: Jul. 10, 2023
(86) PCT No.: PCT/JP2023/025392

§ 371 Date: Feb. 11, 2025

(30) Foreign Application Priority Data
Aug. 19, 2022 (JP) 2022-131371

(51) Int. Cl. H10F 39/00

(52) U.S. Cl. CPC H10F 39/8033; H10F 39/8067; H10F 39/807; H10F 39/809; H10F 39/811

(57) ABSTRACT

Provided is a photodetection device capable of suppressing characteristic fluctuation of a photoelectric conversion element without requiring a complicated circuit.

A photodetection device according to the present technology includes: a first semiconductor substrate provided with a photoelectric conversion element having an avalanche multiplication region and having first and second surfaces facing each other; a laminated structure disposed on the first surface side and having at least an insulating layer and a conductive layer laminated in this order from a side closer to the first surface; and a potential application structure for applying a potential to the conductive layer. According to the photodetection device of the present technology, it is possible to provide the photodetection device capable of suppressing characteristic fluctuation of the photoelectric conversion element without requiring a complicated circuit.

### TECHNICAL FIELD

The technology according to the present disclosure (hereinafter also referred to as “the present technology”) relates to a photodetection device.

### BACKGROUND ART

Conventionally, a photodetection device including a photoelectric conversion element (for example, APD: avalanche photodiode, SPAD: Single Photon Avalanche Diode, etc.) having an avalanche multiplication region is known.

In the conventional photodetection device, there is a concern that the breakdown voltage fluctuates due to the operation of the photoelectric conversion element, and characteristics such as sensitivity fluctuate, for example.

As a countermeasure against this, a photodetection device including a bias adjustment circuit that controls a voltage applied to a photoelectric conversion element to suppress characteristic fluctuation of the photoelectric conversion element has been proposed (for example, see Patent Document 1).

### CITATION LIST

### Patent Document

Patent Document 1: Japanese Patent Application Laid-Open No. 2021-89962

### SUMMARY OF THE INVENTION

### Problems to be Solved by the Invention

However, for example, in the photodetection device described in Patent Document 1, there is room for improvement in suppressing characteristic fluctuation of the photoelectric conversion element without requiring a complicated circuit.

Therefore, a main object of the present technology is to provide a photodetection device capable of suppressing characteristic fluctuation of a photoelectric conversion element without requiring a complicated circuit.

### Solutions to Problems

The present technology provides a photodetection device including:
a first semiconductor substrate provided with a photoelectric conversion element having an avalanche multiplication region and having first and second surfaces facing each other;
a laminated structure disposed on the first surface side and having at least an insulating layer and a conductive layer laminated in this order from a side closer to the first surface; and
a potential application structure for applying a potential to the conductive layer.

The potential application structure may include: a first wiring layer disposed on a side of the laminated structure opposite to the first semiconductor substrate side and electrically connected to the conductive layer; and a circuit board disposed on a side of the first wiring layer opposite to the laminated structure side and electrically connected to the first wiring layer. The circuit board may include: a second wiring layer bonded facing the first wiring layer; and a second semiconductor substrate disposed on a side of the second wiring layer opposite to the first wiring layer side and provided with a circuit element.

The potential may be supplied from the circuit board.

An external connection terminal connected to an external power supply that generates the potential may be provided on the circuit board.

The potential application structure may include at least a via provided in the laminated structure and electrically connecting the conductive layer and the first wiring layer.

The first wiring layer and an anode of the photoelectric conversion element may be electrically connected via at least a first via provided in the laminated structure, and the first wiring layer and a cathode of the photoelectric conversion element may be electrically connected via at least a second via provided in the laminated structure.

The conductive layer may be provided corresponding to a pixel including at least the photoelectric conversion element, and the via may electrically connect a portion of the conductive layer corresponding to the pixel and the first wiring layer.

A pixel including the photoelectric conversion element and a dummy pixel not including the photoelectric conversion element may be provided side by side along an in-plane direction of the first semiconductor substrate, the conductive layer may be provided corresponding to at least the pixel and the dummy pixel, and the via may electrically connect a portion of the conductive layer corresponding to the dummy pixel and the first wiring layer.

The conductive layer may contain at least one selected from polysilicon, W, Ti, Ta, Ni, and Co.

The laminated structure may have a floating gate structure in which the insulating layer and the conductive layer are alternately laminated in this order from a side close to the first surface.

In the laminated structure, at least the insulating layer, a ferroelectric layer, and the conductive layer may be laminated in this order from a side closer to the first surface.

2M [V/cm]<|Vr|/d<8M [V/cm] may hold where the potential is Vr and a thickness of the insulating layer is d.

When the potential is Vr, a distance between each of an anode electrode and a cathode electrode of the photoelectric conversion element and the conductive layer may be equal to or more than |Vr|[V]/1M [V/cm].

A plurality of pixels including the photoelectric conversion element may be provided along an in-plane direction of the first semiconductor substrate, and the conductive layer may be provided corresponding to the plurality of pixels.

A plurality of pixels including the photoelectric conversion element may be provided along an in-plane direction of the first semiconductor substrate, and the conductive layer may have a plurality of electrically separated regions corresponding to different pixels.

The potential may be generated by a voltage source that applies a voltage to the photoelectric conversion element.

The potential application structure may include a voltage divider that makes a magnitude of the potential variable.

The photoelectric conversion element may include a p-type semiconductor layer and an n-type semiconductor layer that form the avalanche multiplication region, the n-type semiconductor layer may be located on the laminated structure side of the p-type semiconductor layer, and the potential may be a negative potential.

Light may be incident from the second surface side of the first semiconductor substrate.

### BRIEF DESCRIPTION OF DRAWINGS

FIG. 1 is a diagram illustrating a planar configuration example of a photodetection device according to a first embodiment of the present technology.

FIG. 2A is a diagram illustrating a circuit configuration example of each pixel of the photodetection device of FIG. 1.

FIG. 2B is a diagram illustrating an example of recovery action of a breakdown voltage by application of a recovery potential.

FIG. 3 is a diagram illustrating a cross-sectional configuration example of a first pixel of the photodetection device of FIG. 1.

FIG. 4 is a diagram illustrating a cross-sectional configuration example of a second pixel of the photodetection device of FIG. 1.

FIG. 5 is a diagram illustrating a planar configuration example of a conductive layer of the photodetection device of FIG. 1.

FIG. 6 is a diagram illustrating an example of a negative charge removing action by application of a recovery potential.

FIG. 7 is a diagram illustrating a cross-sectional configuration example of a first pixel and a dummy pixel of a photodetection device according to a second embodiment of the present technology.

FIG. 8 is a diagram illustrating a planar configuration example of a conductive layer of the photodetection device of FIG. 7.

FIG. 9 is a diagram illustrating a cross-sectional configuration example of a first pixel, a dummy pixel, and an external connection terminal of a photodetection device according to a third embodiment of the present technology.

FIG. 10 is a diagram illustrating a cross-sectional configuration example of a first pixel of a photodetection device according to a fourth embodiment of the present technology.

FIG. 11 is a diagram illustrating a cross-sectional configuration example of a first pixel of a photodetection device according to a fifth embodiment of the present technology.

FIG. 12 is a diagram illustrating a planar configuration example of a conductive layer of a photodetection device according to a sixth embodiment of the present technology.

FIG. 13A is a diagram illustrating a circuit configuration example 1 of each pixel of the photodetection device of FIG. 12, and FIG. 13B is a diagram illustrating a circuit configuration example 2 of each pixel of the photodetection device of FIG. 12.

FIG. 14 is a diagram illustrating a cross-sectional configuration example of a first pixel of a photodetection device according to a seventh embodiment of the present technology.

FIG. 15 is a diagram illustrating a cross-sectional configuration example of a first pixel of a photodetection device according to an eighth embodiment of the present technology.

FIG. 16 is a diagram illustrating a circuit configuration for each pixel of a photodetection device according to a ninth embodiment of the present technology.

FIG. 17 is a diagram illustrating a usage example of a photodetection device to which the present technology is applied.

FIG. 18 is a functional block diagram of an example of an electronic device including the photodetection device to which the present technology is applied.

FIG. 19 is a block diagram illustrating an example of a schematic configuration of a vehicle control system.

FIG. 20 is an explanatory diagram illustrating an example of installation positions of an outside-vehicle information detecting unit and an imaging section.

FIG. 21 is a diagram illustrating an example of a schematic configuration of an endoscopic surgery system.

FIG. 22 is a block diagram illustrating an example of a functional configuration of a camera head and a camera control unit (CCU).

### MODE FOR CARRYING OUT THE INVENTION

Hereinafter, preferred embodiments of the present technology will be described in detail with reference to the accompanying drawings. Note that, in the present specification and drawings, components having substantially the same functional configuration are denoted by the same reference signs, and redundant description is omitted. The embodiments to be described below provide representative embodiments of the present technology, and the scope of the present technology is not to be narrowly interpreted according to those embodiments. In the present specification, even in a case where it is described that the photodetection device according to the present technology exhibits a plurality of effects, the photodetection device according to the present technology is only required to exhibit at least one effect. The effects described in the present specification are merely examples and are not limited, and other effects may be exerted.

Furthermore, the description will be given in the following order.
0. Introduction
1. Photodetection device according to first embodiment of present technology
2. Photodetection device according to second embodiment of present technology
3. Photodetection device according to third embodiment of present technology
4. Photodetection device according to fourth embodiment of present technology
5. Photodetection device according to fifth embodiment of present technology
6. Photodetection device according to sixth embodiment of present technology
7. Photodetection device according to seventh embodiment of present technology
8. Photodetection device according to eighth embodiment of present technology
9. Photodetection device according to ninth embodiment of present technology
10. Modification of present technology
11. Use example of photodetection device to which present technology is applied
12. Another usage example of photodetection device to which present technology is applied
13. Application example to mobile body
14. Application example to endoscopic surgery system

### 0. Introduction

Conventionally, in a photodetection device including a photoelectric conversion element (for example, APD, SPAD, and the like) having an avalanche multiplication region, a bias voltage applied to the photoelectric conversion element is adjusted (bias adjustment) to suppress characteristic fluctuation of the photoelectric conversion element (for example, see Patent Document 1). However, the conventional photodetection device requires a complicated circuit such as a bias adjustment circuit.

Therefore, as a result of intensive studies, the inventors have developed a photodetection device according to the present technology as a photodetection device capable of suppressing characteristic fluctuation of a photoelectric conversion element without requiring a complicated circuit.

In addition, the conventional photodetection device has some problems as follows.
When the magnitude of the breakdown voltage increases, bias adjustment becomes difficult depending on the maximum supply voltage of the bias voltage source, and there is a possibility that characteristic fluctuation of the photoelectric conversion element cannot be sufficiently suppressed.
In particular, in a case where the photoelectric conversion element is the SPAD, when the magnitude of the breakdown voltage increases, the extract bias voltage (voltage equal to or higher than the breakdown voltage) applied to the SPAD also increases, and the power consumption increases.
In particular, in a case where the photodetection device has a pixel array, it is difficult to adjust a bias for each pixel, and there is a possibility that characteristic fluctuation of the photoelectric conversion element of each pixel cannot be sufficiently suppressed.

The photodetection device according to the present technology can also solve the above problem.

Hereinafter, some embodiments of a photodetection device according to the present technology will be described in detail with reference to the drawings.

### 1. Photodetection Device According to First Embodiment of Present Technology

### [Outline of Photodetection Device]

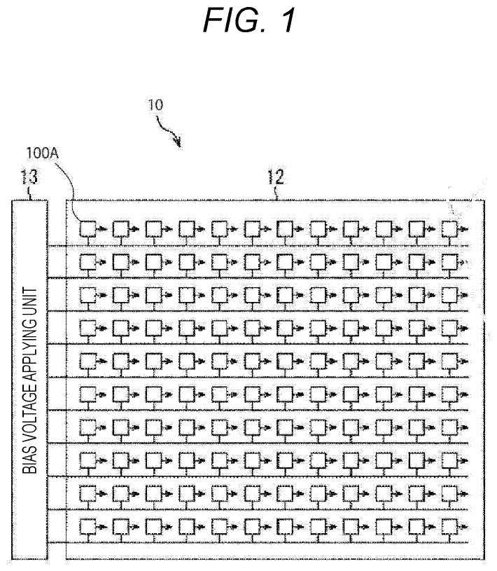

FIG. 1 is a diagram illustrating a planar configuration example of a photodetection device 10 according to a first embodiment of the present technology. As illustrated in FIG. 1, the photodetection device 10 includes a pixel array 12 and a bias voltage applying unit 13.

In the pixel array 12, a plurality of pixels 100A having a light receiving surface that receives light condensed by an optical system (not illustrated) is disposed in a matrix. The bias voltage applying unit 13 applies a bias voltage to each pixel 100A of the pixel array 12.

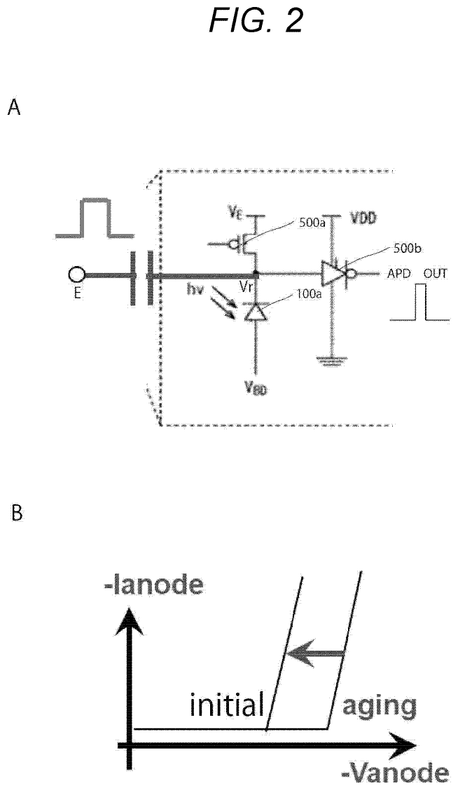

FIG. 2A is a diagram illustrating a circuit configuration example of each pixel of the photodetection device of FIG. 1. As illustrated in FIG. 2A, each pixel 100A includes a photoelectric conversion element 100a having an avalanche multiplication region, a p-type MOSFET (Metal-Oxide-Semiconductor Field-Effect Transistor) 500a, and a CMOS inverter 500b.

The photoelectric conversion element 100a converts the incident light into an electric signal by photoelectric conversion and outputs the electric signal. The photoelectric conversion element 100a is, for example, a SPAD, and has a characteristic that, for example, when a large negative voltage (for example, an extract bias voltage: a negative voltage having an absolute value equal to or greater than an absolute value of a breakdown voltage VBD) that causes avalanche multiplication is applied to the cathode, electrons generated in response to incidence of one photon cause avalanche multiplication, and a large current flows. When the voltage due to the electrons avalanche multiplied by the photoelectric conversion element 100a reaches the breakdown voltage V_{BD}, a p-type MOSFET 500a emits the electrons multiplied by the photoelectric conversion element 100a and performs quenching to return to an initial voltage. The CMOS inverter 500b shapes the voltage generated by the electrons multiplied by the photoelectric conversion element 100a, thereby outputting a detection signal (APD OUT) in which a pulse waveform is generated with the arrival time of one photon as a starting point.

From the photodetection device 10 configured as described above, a detection signal (light reception signal) is output for each pixel 100A and supplied to an arithmetic processing unit (not illustrated) in a subsequent stage. For example, the arithmetic processing unit performs arithmetic processing of obtaining the distance to a subject on the basis of the timing at which the pulse indicating the arrival time of one photon is generated in each light receiving signal, and obtains the distance for each pixel 100A. Then, on the basis of these distances, a distance image in which the distances to the subject detected by the plurality of pixels 100 are planarly arranged is generated.

### (Fluctuation of Breakdown Voltage)

FIG. 2B is a diagram illustrating an example of a recovery action of the breakdown voltage V_{BD} by application of a recovery potential. In FIG. 2B, the horizontal axis represents the voltage between the anode and the cathode of the SPAD, and the vertical axis represents the current flowing through the SPAD.

As illustrated in FIG. 2B, for example, in a case where the breakdown voltage V_{BD} of the photoelectric conversion element 100a is negative and |V_{BD}| is larger than the designed value (initial set value (initial in FIG. 2)) (aging in FIG. 2B), it is considered that a negative charge e (electron) is injected into the cathode. This state is hardly eliminated even after the quenching, and the next photon is detected in a state where IV_{BD} l is larger than the design value (state of aging in FIG. 2B). Therefore, if the negative charge e can be removed, it is possible to suppress the fluctuation of the breakdown voltage V_{BD} from the design value, that is, to recover the breakdown voltage V_{BD} (return to initial in FIG. 2B).

### (Recovery Potential)

As an example, a recovery potential Vr for recovering the breakdown voltage V_{BD} is applied to the cathode of the photoelectric conversion element 100a by a potential application structure PAS described later. The recovery potential Vr is a negative potential that dissipates the negative charge e injected into the cathode of the photoelectric conversion element 100a.

In the photodetection device 10, as an example, a negative potential as the recovery potential Vr is applied to the conductive layer disposed in the vicinity of the cathode of the photoelectric conversion element 100a, so that the negative charge e on the cathode side is blown off by the repulsion to suppress fluctuation of the breakdown voltage V_{BD}.

### [Details of Photodetection Device]

### (Overall Configuration)

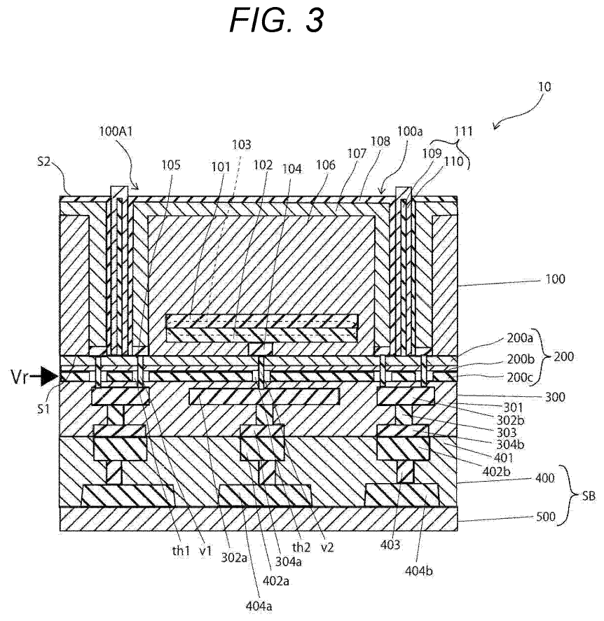

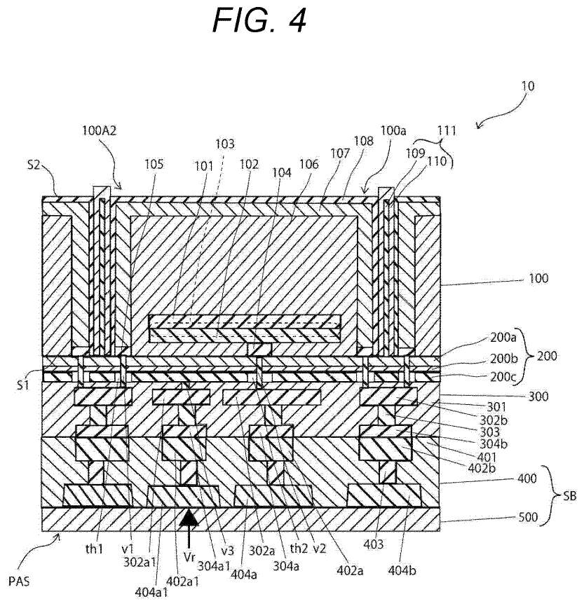

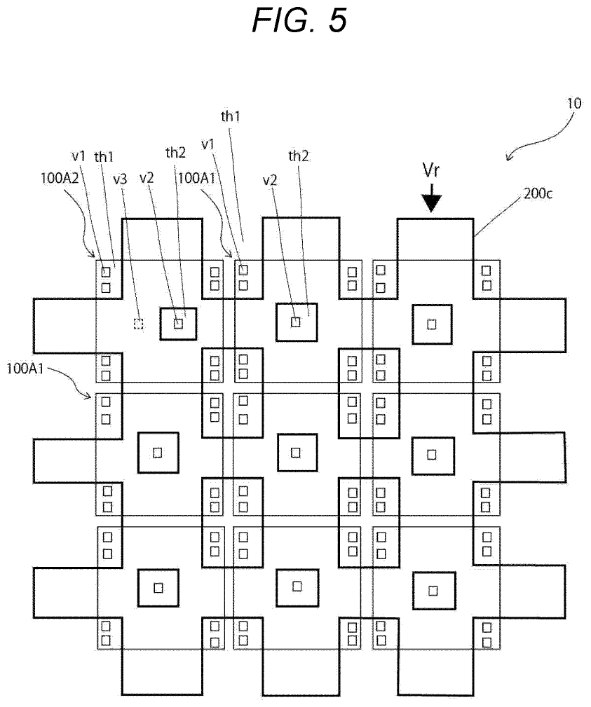

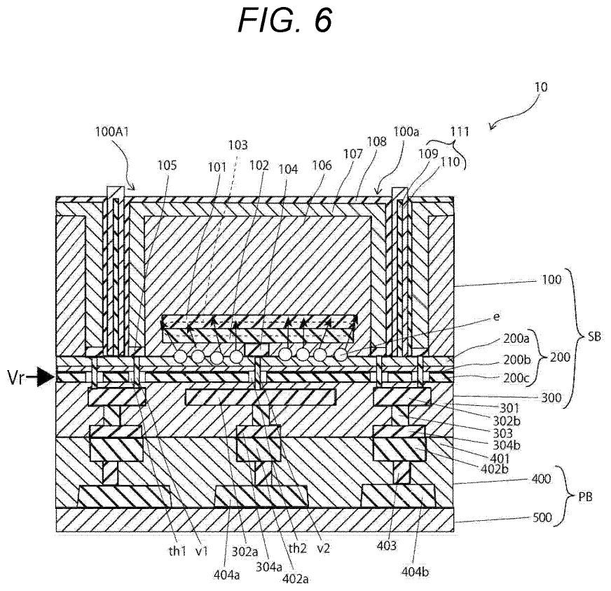

FIG. 3 is a diagram illustrating a cross-sectional configuration example of a first pixel 100A1 (an example of the pixel 100A) of the photodetection device 10. FIG. 4 is a diagram illustrating a cross-sectional configuration example of a second pixel 100A2 (another example of the pixel 100A) of the photodetection device 10. FIG. 5 is a diagram illustrating a planar configuration example of a conductive layer of the photodetection device 10. FIG. 6 is a diagram illustrating an example of a negative charge removing action by application of a recovery potential. Hereinafter, the first and second pixels 100A1 and 100A2 will be described in common unless otherwise specified. In addition, for convenience, the upper side in the cross-sectional views of FIGS. 3 and 4 and the like will be referred to as “upper”, and the lower side will be referred to as “lower”.

As an example, as illustrated in FIGS. 3 and 4, the photodetection device 10 includes a first semiconductor substrate 100 provided with a photoelectric conversion element 100a having an avalanche multiplication region 103, a laminated structure 200 including a conductive layer 200c, and a potential application structure PAS for applying a potential to the conductive layer 200c.

A plurality of pixels 100A each having the photoelectric conversion element 100a is provided side by side along the in- plane direction of the first semiconductor substrate 100. The plurality of pixels 100A includes at least two first pixels 100A1 and at least one second pixel 100A2. In the plurality of pixels 100A, for example, one pixel 100A may be the second pixel 100A2, and all the remaining pixels 100A may be the first pixel 100A1.

As an example, the first semiconductor substrate 100 has a first surface S1 (lower surface) and a second surface S2 (upper surface) facing each other in the thickness direction (vertical direction). The first semiconductor substrate 100 is, for example, a semiconductor substrate obtained by thinly slicing single crystal silicon, and the p-type or n-type impurity concentration is controlled, and the photoelectric conversion element 100a is formed for each pixel 100A. The second surface S2 of the first semiconductor substrate 100 is a light incident surface.

The first semiconductor substrate 100 is, for example, a Si substrate, a Ge substrate, a GaAs substrate, an InGaAs substrate, or the like.

As an example, the laminated structure 200 is disposed on the first surface S1 side (lower surface side, front surface side) of the first semiconductor substrate 100. In the laminated structure 200, the first insulating layer 200a, the second insulating layer 200b, and the conductive layer 200c are laminated in this order from the side (upper side) close to the first surface S1. That is, the photodetection device 10 is a back surface irradiation type photodetection device in which light is incident (irradiated) from the second surface S2 side which is the back surface side of the first semiconductor substrate 100. The first and second insulating layers 200a and 200b are also collectively referred to as “insulating layers”. Here, the insulating layer has a multilayer structure.

The potential application structure PAS includes a first wiring layer 300 disposed on the side (lower side) of the laminated structure 200 opposite to the first semiconductor substrate 100 side and electrically connected to the conductive layer 200c, and a circuit board SB disposed on the side (lower side) of the first wiring layer 300 opposite to the laminated structure 200 side and electrically connected to the first wiring layer 300. The potential application structure PAS is provided at least in the laminated structure 200 and includes a via v3 electrically connecting the conductive layer 200c and the first wiring layer 300 (see FIG. 4). The conductive layer 200c is provided corresponding to at least each pixel 100A, and the via v3 electrically connects a portion of the conductive layer 200c corresponding to the second pixel 100A2 and the first wiring layer 300 (see FIG. 4). The first semiconductor substrate 100, the laminated structure 200, and the first wiring layer 300 may be collectively referred to as a “pixel substrate” or a “sensor substrate”.

The circuit board SB includes a second wiring layer 400 bonded facing the first wiring layer 300, and a second semiconductor substrate 500 disposed on the side (lower side) of the second wiring layer 400 opposite to the first wiring layer 300 side and provided with a circuit element. Here, the recovery potential Vr is supplied from the circuit board SB to the cathode of the photoelectric conversion element 100a. The circuit board SB supplies the recovery potential Vr to the photoelectric conversion element 100a when the photoelectric conversion element 100a is not operated (for example, after quenching and before application of an excess bias voltage). The magnitude of the recovery potential Vr is, for example, equal to the magnitude of the breakdown voltage of the photoelectric conversion element 100a, but may be less than the breakdown voltage or greater than the breakdown voltage. The circuit board SB may be referred to as a “processing board”. The recovery potential Vr may be applied every time the photoelectric conversion element 100a is driven, or may be applied every time the photoelectric conversion element 100a is driven a plurality of times.

The second semiconductor substrate 500 is, for example, a logic substrate (a semiconductor substrate on which a logic circuit is formed). The second semiconductor substrate 500 is provided with, for example, a bias voltage applying unit 13 as a circuit element, a p-type MOSFET 500a, a CMOS inverter 500b, and the like.

The second semiconductor substrate 500 is, for example, a Si substrate, a Ge substrate, a GaAs substrate, an InGaAs substrate, or the like.

The bias voltage applying unit 13 may apply a bias voltage to the photoelectric conversion element 100a and apply the recovery potential Vr to the conductive layer 200c when the photoelectric conversion element 100a is not operated (not driven). In this case, a common power source (for example, reference numeral E in FIG. 2A) for generating the bias voltage and the recovery potential Vr may be used, or separate power sources may be used. For example, the power source is provided on the circuit board SB.

In addition, the potential application structure PAS may include a recovery potential applying unit for applying the recovery potential Vr on the circuit board SB separately from the bias voltage applying unit 13. Also in this case, a common power source may be used as the power source for generating the bias voltage and the recovery potential Vr, or separate power sources may be used. For example, the power source is provided on the circuit board SB.

The first and second wiring layers 300 and 400 internally include wiring for supplying a voltage applied to the photoelectric conversion element 100a, wiring for extracting electrons generated in the photoelectric conversion element 100a from the first semiconductor substrate 100, and the like.

### (Photoelectric Conversion Element)

The photoelectric conversion element 100a includes a p-type diffusion layer 101 (p-type semiconductor layer), an n-type diffusion layer 102 (n-type semiconductor layer), a high-concentration n-type diffusion layer 104, a high-concentration p-type diffusion layer 105, an n-well 106, a hole accumulation layer 107, and a pinning layer 108 formed on the first semiconductor substrate 100. In the photoelectric conversion element 100a, the avalanche multiplication region 103 is formed by a depletion layer formed in a pn junction which is a junction between the p-type diffusion layer 101 and the n-type diffusion layer 102.

The n-well 106 is formed by controlling the impurity concentration of the first semiconductor substrate 100 to n-type, and forms an electric field that transfers electrons generated by photoelectric conversion in the photoelectric conversion element 100a to the avalanche multiplication region 103. Note that, instead of the n-well 106, a p-well may be formed by controlling the impurity concentration of the first semiconductor substrate 100 to p-type.

The p-type diffusion layer 101 is a high-concentration p-type diffusion layer (p+) disposed in the vicinity of the first surface S1 of the first semiconductor substrate 100 and on the side (upper side) of the n-type diffusion layer 102 opposite to the laminated structure 200 side, and is formed over substantially the entire surface of the photoelectric conversion element 100a.

The n-type diffusion layer 102 is a high-concentration n-type diffusion layer (n+) disposed in the vicinity of the first surface S1 of the first semiconductor substrate 100 and on the laminated structure 200 side (lower side) of the p-type diffusion layer 101, and is formed over substantially the entire surface of the photoelectric conversion element 100a.

The high-concentration n-type diffusion layer 104 is a high-concentration n-type diffusion layer (n++) disposed in the vicinity of the first surface S1 of the first semiconductor substrate 100 and on the first surface S1 side (lower side) of the n-type diffusion layer 102, and is formed in the vicinity of the central portion in the plane of the photoelectric conversion element 100a. The high-concentration n-type diffusion layer 104 functions as a cathode electrode of the photoelectric conversion element 100a. Note that the n-type diffusion layer 102 and the high-concentration n-type diffusion layer 104 may be integrally configured.

The high-concentration p-type diffusion layer 105 is a p-type diffusion layer (p++) formed so as to surround the outer periphery of the n-well 106 in the vicinity of the first surface S1 of the first semiconductor substrate 100, and functions as an anode electrode of the photoelectric conversion element 100a.

The hole accumulation layer 107 is a p-type diffusion layer (p) formed so as to cover the side surface and the bottom surface (upper surface) of the n-well 106, and accumulates holes. In addition, the hole accumulation layer 107 is electrically connected to the anode of the photoelectric conversion element 100a to enable bias adjustment. As a result, the hole concentration of the hole accumulation layer 107 is enhanced, and pinning including the pinning layer 108 is strengthened, so that, for example, generation of dark current can be suppressed.

The pinning layer 108 is a high-concentration p-type (p+) diffusion layer formed so as to cover the outer surface of the hole accumulation layer 107, and suppresses, for example, generation of a dark current, similarly to the hole accumulation layer 107.

The avalanche multiplication region 103 is a high electric field region formed on the boundary surface (pn junction) between the p-type diffusion layer 104 and the n-type diffusion layer 102 by a large negative voltage (for example, an excess bias voltage) applied to the n-type diffusion layer 102 via the high-concentration n-type diffusion layer 101, and multiplies electrons generated by one photon incident on the photoelectric conversion element 100a.

### (Inter-Pixel Separation Portion)

In the photodetection device 10, each photoelectric conversion element 100a is insulated and separated by an inter-pixel separation portion 111 having a double structure including a metal film 109 and an insulating film 110 formed between adjacent photoelectric conversion elements 100a. For example, the inter-pixel separation portion 111 is formed so as to penetrate from the second surface S2 to the first surface S1 of the first semiconductor substrate 100.

The metal film 109 is a film including a metal (for example, W or the like) that reflects light. The insulating film 110 is a film having an insulating property such as Si02. For example, the inter-pixel separation portion 111 is formed by embedding the metal film 109 in the first semiconductor substrate 100 so as to be covered with the insulating film 110, and the adjacent photoelectric conversion elements 100a are electrically and optically separated by the inter-pixel separation portion 111.

(Laminated Structure)

The first insulating layer 200a includes Si02, for example. The second insulating layer 200b includes SiN, for example.

The conductive layer 200c is provided corresponding to the plurality of pixels 100A (see FIG. 5). In the conductive layer 200c, a first through hole th1 is formed at a position corresponding to the high-concentration p-type diffusion layer 105 (four corners of each pixel 100A), and a second through hole th2 is formed at a position corresponding to the high-concentration n-type diffusion layer 104. The conductive layer 200c has, for example, a lattice shape in a plan view by forming a plurality of first through holes thl in a matrix arrangement in a plan view, and second through holes th2 are formed at intersections of the lattice. The conductive layer 200c reflects the light transmitted through the photoelectric conversion element 100a among the light incident from the second surface S2 side to the photoelectric conversion element 100a. Note that the first through hole th1 formed at the end of the conductive layer 200c may have a notch shape.

The conductive layer 200c preferably contains at least one selected from p-Si (polysilicon), W, Ti, Ta, Ni, and Co. For example, a metal such as W, Ti, Ta, Ni, or Co may be used, or a compound such as p-Si which is polycrystalline Si, WSi, TiSi₂, TaSi₂, NiSi₂, CoSi₂, TiN, or TaN may be used.

The first wiring layer 300 and the anode of the photoelectric conversion element 100a are electrically connected via at least a first via vl provided in the laminated structure 200. The first wiring layer 300 and the cathode of the photoelectric conversion element 100a are electrically connected via at least a second via v2 provided in the laminated structure 200. The first and second vias v1 and v2 include, for example, W, Cu, Al, or the like.

When a negative potential as the recovery potential Vr is applied to the conductive layer 200c, the negative charge e injected into the cathode of the photoelectric conversion element 100a is blown off by the repulsion (see FIG. 6), and the breakdown voltage of the photoelectric conversion element 100a can be recovered.

Here, in order to apply a desired recovery potential Vr to the photoelectric conversion element 100a, the following Formula (1) is preferably satisfied between the recovery potential Vr and the thickness d (here, the sum of the thicknesses of the first and second insulating layers 200a and 200b) of the insulating layer.

$$2 M [ V / cm ] < \vert Vr \vert / d < 8 M [ V / cm ] \qquad ( 1 )$$

For example, in a case where a desired recovery potential Vr is −20 V, it is preferable to set d to 25 nm to 100 nm according to Formula (1).

In addition, in order to suppress an adverse effect caused by applying a relatively large negative potential to the conductive layer 200c, a distance (here, the thickness d of the insulating layer) in a laminating direction (vertical direction) between each of the high-concentration p-type diffusion layer 105 as an anode electrode and the high-concentration n-type diffusion layer 104 as a cathode electrode of the photoelectric conversion element 100a and the conductive layer 200c is preferably |Vr|[V] /1M [V/cm] or more. For example, in a case where the desired recovery potential Vr is −20 V, d is preferably 200 nm or more.

### (First Wiring Layer)

The first wiring layer 300 includes an insulating film 301, and metal wirings 302a and 302b and metal pads 304a and 304b formed in the insulating film 301. The insulating film 301 includes, for example, SiO₂, SiN, SiON, or the like. Each metal wiring and each metal pad include, for example, Cu, Al, W, or the like.

The metal wiring 302a is formed so as to overlap at least the avalanche multiplication region 103.

The metal wiring 302b is formed so as to surround the outer periphery of the metal wiring 302a and overlap the high-concentration p-type diffusion layer 105.

The first via vl is formed so as to penetrate the first insulating layer 200a, the second insulating layer 200b, and the conductive layer 200c of the laminated structure 200, and the surface layer (the upper layer of the insulating film 301) of the first wiring layer 300 on the laminated structure 200 side, and electrically connects a high-concentration p-type diffusion layer 105 and the metal wiring 302b. The first via v1 penetrates the first through hole th1 of the conductive layer 200c without being in contact with the inner wall surface of the first through hole th1 (in a state of being insulated from the conductive layer 200c). Here, the first and second through holes th1 and th2 are voids, but at least one of them may be filled with, for example, an insulating material.

The metal wiring 302b and the metal pad 304b are electrically connected via a via 303. The metal wiring 302b and the metal pad 304b are shared between the adjacent pixels 100A. That is, in the pixel array 12 of the photodetection device 10, anodes are electrically connected between the pixels 100A (anode common). The via 303 includes, for example, W, Cu, Al, or the like.

The second via v2 is formed so as to penetrate the first insulating layer 200a, the second insulating layer 200b, and the conductive layer 200c of the laminated structure 200, and the surface layer (the upper layer of the insulating film 301) of the first wiring layer 300 on the laminated structure 200 side, and electrically connects the high-concentration n-type diffusion layer 104 and the metal wiring 302a. The second via v2 penetrates the second through hole th2 of the conductive layer 200c without being in contact with the inner wall surface of the first through hole th2 (in a state of being insulated from the conductive layer 200c).

The metal wiring 302a and the metal pad 304a are electrically connected via the via 303. The metal wiring 302a and the metal pad 304a are provided independently (electrically separated) for each pixel 100A. That is, in the pixel array 12 of the photodetection device 10, the cathodes are electrically separated between the pixels 100A. This enables independent driving for each pixel 100A.

In the second pixel 100A2 illustrated in FIG. 4, a metal wiring 302a l and a metal pad 304a l are further provided in the insulating film 301 of the first wiring layer 300. Each metal pad and each electrode pad include, for example, Cu, Al, W, or the like.

The metal wiring 302a l and the metal pad 304a l are electrically connected via the via 303.

The metal wiring 302a l is electrically connected to the conductive layer 200c via the via v3. The via v3 includes, for example, W, Cu, Al, or the like.

### (Second Wiring Layer)

The second wiring layer 400 includes an insulating film 401, metal pads 402a and 402b formed in the insulating film 401, and electrode pads 404a and 404b. The insulating film 401 includes, for example, SiO₂, SiN, SiON, or the like. Each metal pad and each electrode pad include, for example, Cu, Al, W, or the like.

The metal pad 402a is electrically and mechanically bonded to the metal pad 304a of the first wiring layer 300 by metal bonding (for example, Cu—Cu bonding or the like). The metal pad 402b is electrically and mechanically bonded to the metal pad 304b of the first wiring layer 300 by metal bonding (for example, Cu—Cu bonding or the like).

The metal pad 402a and the electrode pad 404a are electrically connected via a via 403. The metal pad 402b and the electrode pad 404b are electrically connected via a via 403. The via 403 includes, for example, W, Cu, Al, or the like.

The electrode pads 404a and 404b are electrically connected to the logic substrate as the second semiconductor substrate 500.

In the second pixel 100A2 illustrated in FIG. 4, a metal pad 402a1 and an electrode pad 404a1 are further provided in the insulating film 401 of the second wiring layer 400. Each metal pad and each electrode pad include, for example, Cu, Al, W, or the like.

The metal pad 402a1 is electrically and mechanically bonded to the metal pad 304a1 of the first wiring layer 300 by metal bonding (for example, Cu—Cu bonding or the like).

The metal pad 402a1 and the electrode pad 404a1 are electrically connected via a via 403.

As can be seen from the above description, the electrode pad 404a is electrically connected to the high-concentration n-type diffusion layer 104 via the via 403, the metal pad 402a, the metal pad 304a, the via 303, the metal wiring 302a, and the via v2. Therefore, in the photoelectric conversion element 100a, a large negative voltage (for example, an excess bias voltage) can be supplied from the logic substrate as the second semiconductor substrate 500 to the n-type diffusion layer 102.

Further, the electrode pad 404b is electrically connected to the hole accumulation layer 107 via the via 403, the metal pad 402b, the metal pad 304b, the via 303, the metal wiring 302b, the via v1, and the high-concentration p-type diffusion layer 105. Therefore, in the photoelectric conversion element 100a, the anode of the photoelectric conversion element 100a electrically connected to the hole accumulation layer 107 is connected to the electrode pad 404b, so that it is possible to adjust the bias with respect to the hole accumulation layer 107 via the electrode pad 404b.

Furthermore, in the second pixel 100A2, the electrode pad 404a1 is electrically connected to the conductive layer 200c via the via 403, the metal pad 402a1, the metal pad 304a1, the via 303, the metal wiring 302a1, and the via v3. Therefore, the recovery potential Vr can be supplied from the logic substrate as the second semiconductor substrate 500 to the conductive layer 200c.

Furthermore, the pixel 100A is formed such that the conductive layer 200c covers substantially the entire area of the avalanche multiplication region 103 and the metal film 109 penetrates the first semiconductor substrate 100. That is, the pixel 100A has a reflection structure in which substantially all surfaces other than the light incident surface of the photoelectric conversion element 100a are surrounded by the conductive layer 200c and the metal film 109. As a result, the occurrence of optical crosstalk can be suppressed, and the sensitivity of the photoelectric conversion element 100a can be improved.

The photodetection device 10 according to the first embodiment described above includes the photoelectric conversion element 100a having the avalanche multiplication region 103, the first semiconductor substrate 100 having the first and second surfaces S1 and S2 facing each other, the laminated structure 200 disposed on the first surface S1 side and in which at least the insulating layer (first and second insulating layers 200a and 200b) and the conductive layer 200c are laminated in this order from the side close to the first surface S1, and the potential application structure PAS for applying a potential to the conductive layer 200c.

In the photodetection device 10, for example, a complicated circuit such as a bias adjustment circuit is not required.

That is, according to the photodetection device 10, it is possible to provide a photodetection device capable of suppressing characteristic fluctuation of the photoelectric conversion element 100a without requiring a complicated circuit.

Furthermore, according to the photodetection device 10, since the fluctuation of the breakdown voltage of the photoelectric conversion element 100a is suppressed by the potential application structure PAS that applies a potential to the conductive layer 200c regardless of the bias adjustment circuit, for example, even if the magnitude of the breakdown voltage temporarily increases, the breakdown voltage can be immediately recovered regardless of the magnitude, and eventually, the characteristic fluctuation of the photoelectric conversion element 100a can be sufficiently suppressed.

Furthermore, according to the photodetection device 10, in particular, in a case where the photoelectric conversion element 100a is the SPAD, since it is possible to suppress the magnitude of the breakdown voltage from continuously increasing, it is also possible to suppress the magnitude of the excess bias voltage (voltage equal to or higher than the breakdown voltage) applied to the SPAD from continuously increasing, and eventually, it is possible to suppress an increase in power consumption.

Furthermore, according to the photodetection device 10, even in a case where a pixel array is provided, it is possible to uniformly suppress fluctuation of the breakdown voltage of the photoelectric conversion element 100a of a plurality of pixels, and eventually, it is possible to sufficiently suppress characteristic fluctuation of the photoelectric conversion element of each pixel.

### 2. Photodetection Device According to Second Embodiment of Present Technology

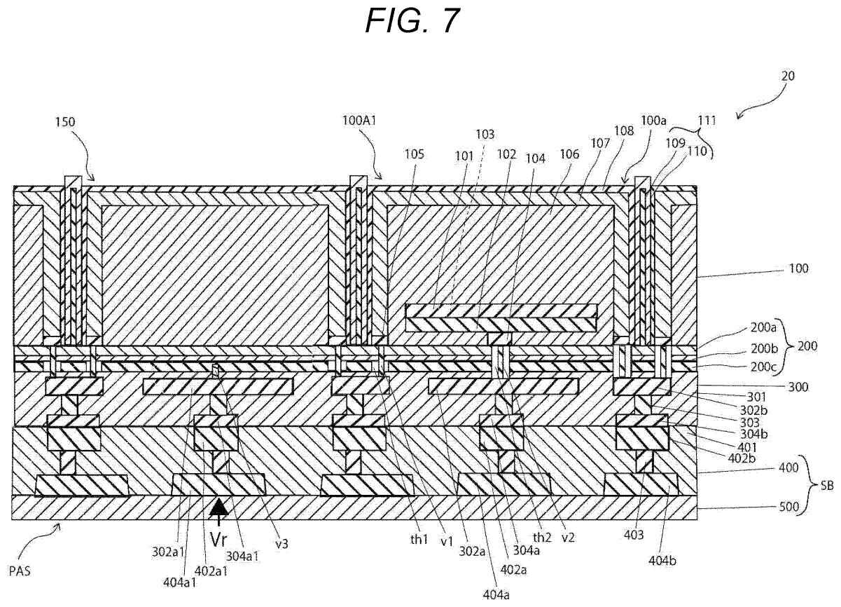

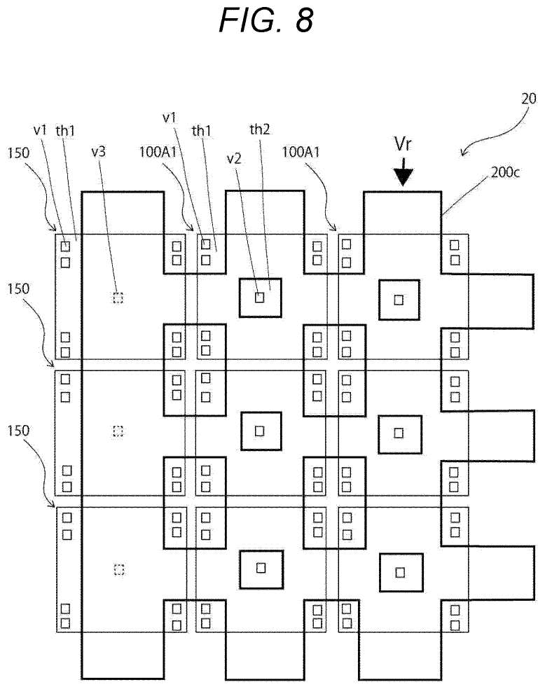

FIG. 7 is a diagram illustrating a cross-sectional configuration example of a first pixel 100A1 and a dummy pixel 150 of a photodetection device 20 according to a second embodiment of the present technology. FIG. 8 is a diagram illustrating a planar configuration example of a conductive layer 200c of a photodetection device 20.

As illustrated in FIG. 8, the photodetection device 20 has a substantially similar configuration to the photodetection device 10 according to the first embodiment except that the dummy pixel 150 is provided instead of the second pixel 100A2.

In the photodetection device 20, as illustrated in FIG. 7, the first pixel 100A1 including a photoelectric conversion element 100a and the dummy pixel 150 not including a photoelectric conversion element 100a are provided side by side along the in-plane direction of a first semiconductor substrate 100. The conductive layer 200c is provided corresponding to at least the first pixel 100A1 and the dummy pixel 150. A via v3 electrically connects the portion of the conductive layer 200c corresponding to the dummy pixel 150 and a first wiring layer 300.

The dummy pixel 150 has a substantially similar configuration to the second pixel 100A2 (see FIG. 4) except that it does not include the photoelectric conversion element 100a and the multilayer wiring connected to the cathode of the photoelectric conversion element 100a. For example, a plurality of dummy pixels 150 is arranged along the outer peripheral portion of the pixel array (see FIG. 8). Note that the number of dummy pixels 150 is not limited to a plurality, and at least one dummy pixel may be provided.

In the photodetection device 20, a portion of the conductive layer 200c corresponding to the dummy pixel 150 is electrically connected to a metal wiring 302a1 via the via v3. In the photodetection device 20, a negative potential as a recovery potential Vr can be applied from the logic substrate as a second semiconductor substrate 500 to the entire conductive layer 200c via an electrode pad 404a1, a via 403, a metal pad 402a1, a metal pad 304a1, a via 303, the metal wiring 302a1, and the via v3. When a negative potential as the recovery potential Vr is applied to the conductive layer 200c, a negative charge e injected into the cathode of the photoelectric conversion element 100a of the first pixel 100A1 is blown off by the repulsion, and the breakdown voltage of the photoelectric conversion element 100a can be recovered.

According to the photodetection device 20, since the multilayer wiring connecting the conductive layer 200c and the logic substrate as the second semiconductor substrate 500 is provided in the dummy pixel 150 and there is a margin in the installation space of the wiring, the multilayer wiring is easily formed.

### 3. Photodetection Device According to Third Embodiment of Present Technology

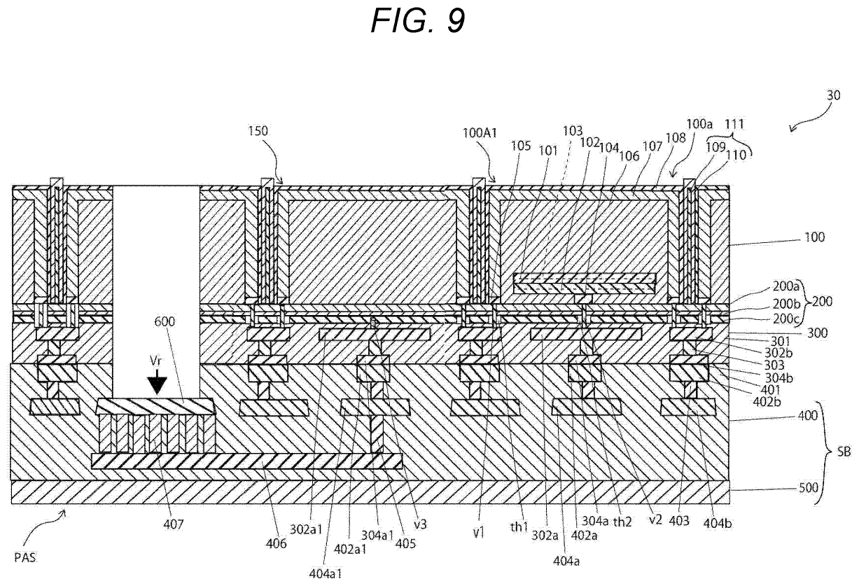

FIG. 9 is a diagram illustrating a cross-sectional configuration example of a first pixel 100A1, a dummy pixel 150, and an external connection terminal 600 of a photodetection device 30 according to a third embodiment of the present technology.

As illustrated in FIG. 9, the photodetection device 30 has a substantially similar configuration to the photodetection device 20 according to the second embodiment except that the external connection terminal 600 connected to an external power supply that generates a recovery potential Vr is provided on a circuit board SB.

In the photodetection device 30, a connection space between a second wiring layer 400 and the external power supply is formed in a part of the outer peripheral side of the dummy pixel 150 in the pixel array. The external connection terminal 600 is provided on an insulating film 401 so as to be exposed to the connection space. The position of the external connection terminal 600 in the laminating direction is, for example, substantially the same as the position of an electrode pad 404a1 in the laminating direction (vertical direction).

A metal wiring 406 is formed on a second semiconductor substrate 500 side of the external connection terminal 600 and an electrode pad 404a1 in the insulating film 401. The metal wiring 406 is electrically connected to the external connection terminal 600 via a plurality of vias 407, and is electrically connected to the electrode pad 404a1 via a vias 405. Therefore, the external connection terminal 600 is electrically connected to a conductive layer 200c via the plurality of vias 407, the metal wiring 406, the vias 405, the electrode pad 404a1, a via 403, a metal pad 402a1, a metal pad 304a1, a vias 303, a metal wiring 302a1, and a via v3.

In the photodetection device 30, when a negative potential as the recovery potential Vr is generated by the external power supply connected to the external connection terminal 600, the recovery potential Vr is applied to the conductive layer 200c, the negative charge e injected into the cathode of the photoelectric conversion element 100a is blown off by the repulsion, and the breakdown voltage of the photoelectric conversion element 100a can be recovered.

According to the photodetection device 30, since the recovery potential Vr is generated by the external power supply, it is not necessary to provide a power supply for generating the recovery potential Vr in the logic substrate as the second semiconductor substrate 500.

### 4. Photodetection Device According to Fourth Embodiment of Present Technology

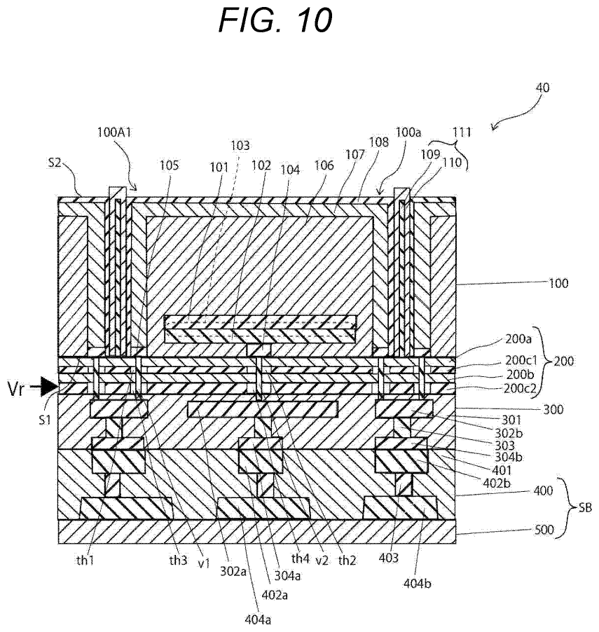

FIG. 10 is a diagram illustrating a cross-sectional configuration example of a first pixel 100A1 of a photodetection device 40 according to a fourth embodiment of the present technology.

In the photodetection device 40, as illustrated in FIG. 10, a laminated structure 200 has a floating gate structure in which an insulating layer and a conductive layer are alternately laminated in this order from the side (upper side) close to a first surface S1. More specifically, in the laminated structure 200, for example, a first insulating layer 200a, a first conductive layer 200c1, a second insulating layer 200b, and a second conductive layer 200c2 are laminated in this order from the side (upper side) close to the first surface S1. In the laminated structure 200, by causing the first conductive layer 200c1 located between the first and second insulating layers 200a and 200b to function as a floating gate, a carrier injection effect similar to that of the EEPROM (flash memory) can be obtained. For the first and second conductive layers 200c1 and 200c2, a material similar to the material of the conductive layer 200c described above can be used. The materials of the first and second conductive layers 200c1 and 200c2 may be the same or different. Here, the laminated structure 200 has two sets of the insulating layer and the conductive layer laminated in order from the side closer to the first surface S1, but may have three or more sets.

In the photodetection device 40, a first through hole th1 is formed in the first conductive layer 200c1, and a third through hole th3 corresponding to the first through hole th1 is formed in the second conductive layer 200c2. Here, a via v1 penetrates first and third through holes thl and th3 without being in contact with any inner wall surface, and electrically connects a metal wiring 302b and a high-concentration p-type diffusion layer 105. Here, each of the first and third through holes th1 and th3 is a void, but at least one of the first and third through holes th1 and th3 may be filled with, for example, an insulating material.

In the photodetection device 40, a second through hole th2 is formed in the first conductive layer 200c1, and a fourth through hole th4 corresponding to the second through hole th2 is formed in the second conductive layer 200c2. Here, the via v2 penetrates the second and fourth through holes th2 and th4 without being in contact with any inner wall surface, and electrically connects a metal wiring 302a and a high-concentration n-type diffusion layer 104. Here, each of the second and fourth through holes th2 and th4 is a void, but at least one of the second and fourth through holes th2 and th4 may be filled with, for example, an insulating material.

The photodetection device 40 includes a second pixel 100A2 or a dummy pixel 150 having a via v3 which is a connection portion between the conductive layer 200c and a multilayer wiring for applying a recovery potential Vr. In the photodetection device 40, the second conductive layer 200c2 is electrically connected to a first wiring layer 300 via the via v3. In the photodetection device 40, a negative charge e injected into a cathode of a photoelectric conversion element 100a is discretized by applying a negative potential as the recovery potential Vr to the second conductive layer 200c2, and injection of a positive charge h (hole) into the first conductive layer 200c1 as a floating gate is urged to recover the breakdown voltage of the photoelectric conversion element 100a. In this case, the magnitude of the recovery potential Vr can be expected to be smaller than that in each of the above embodiments.

Also in the photodetection device 40, when the sum of the thicknesses of the first and second insulating layers 200a and 200b is d, Formula (1) described above is preferably satisfied. For example, in a case where a desired recovery potential Vr is −20 V, d is preferably set to 25 nm to 100 nm from Formula (1) described above.

### 5. Photodetection Device According To Fifth Embodiment of Present Technology

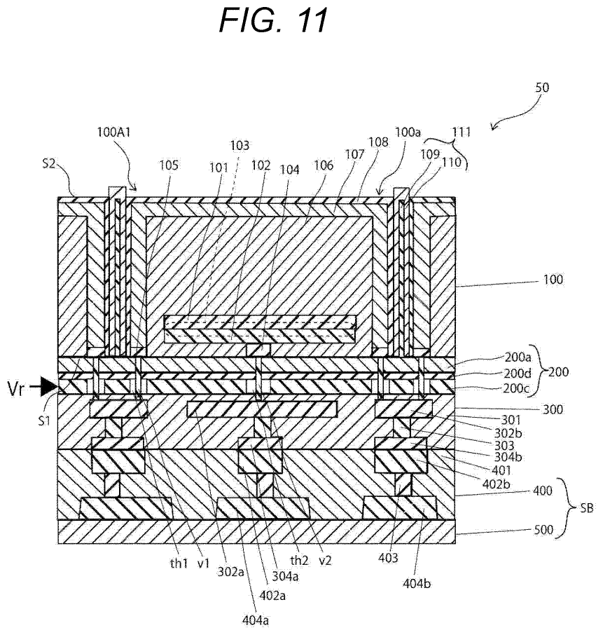

FIG. 11 is a diagram illustrating a cross-sectional configuration example of a first pixel 100A1 of a photodetection device 50 according to a fifth embodiment of the present technology.

In the photodetection device 50, as illustrated in FIG. 11, in a laminated structure 200, at least a first insulating layer 200a (insulating layer), a ferroelectric layer 200d, and a conductive layer 200c are laminated in this order from the side (upper side) close to a first surface S1. In this case, the residual polarization effect can be expected similarly to the FeRAM, and the magnitude (absolute value) of a recovery potential Vr can be reduced.

Examples of the ferroelectric used for the ferroelectric layer 200d include oxides of HfO2, HZO, PZT, SBT, Hf, and Zr, oxides of Pb and ZrTi, and oxides of Sr, Bi, and Ta. The thickness of the ferroelectric layer 200d is, for example, 10 nm to 100 nm.

The photodetection device 50 includes a second pixel 100A2 or a dummy pixel 150 having a via v3 which is a connection portion between the conductive layer 200c and a multilayer wiring for applying the recovery potential Vr. Specifically, in the photodetection device 50, by applying a positive potential (for example, a positive potential of +5 V or less) as the recovery potential Vr to the conductive layer 200c, polarization is generated in the ferroelectric layer 200d in a direction from the conductive layer 200c side toward the first insulating layer 200a side as a polarization direction, and a negative charge e injected into a cathode of a photoelectric conversion element 100a is neutralized with a positive charge h (hole) as a polarization charge to recover the breakdown voltage of the photoelectric conversion element 100a.

In the photodetection device 50, when the thickness of the first insulating layer 200a is d, Formula (1) described above is preferably satisfied. For example, in a case where a desired recovery potential Vr is +5 V, d is preferably set to 25 nm to 100 nm from Formula (1) described above.

### 6. Photodetection Device According to Sixth Embodiment of present Technology

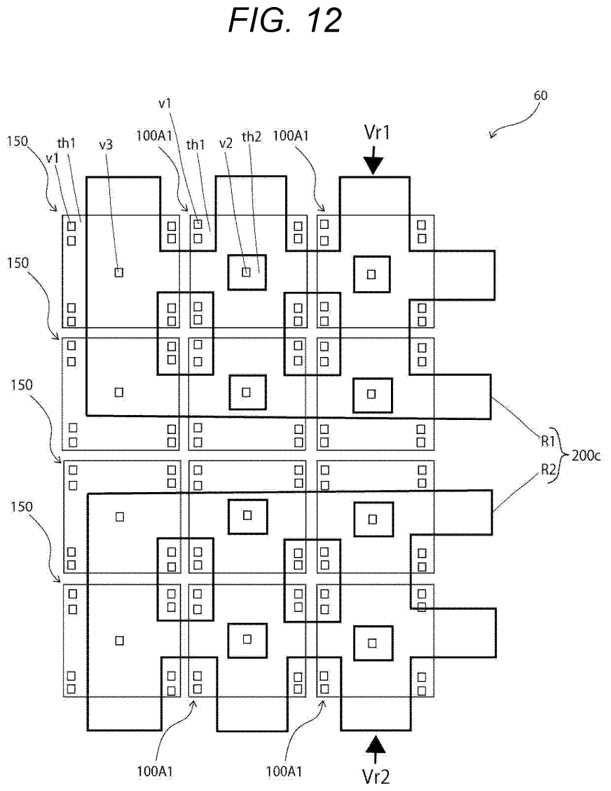

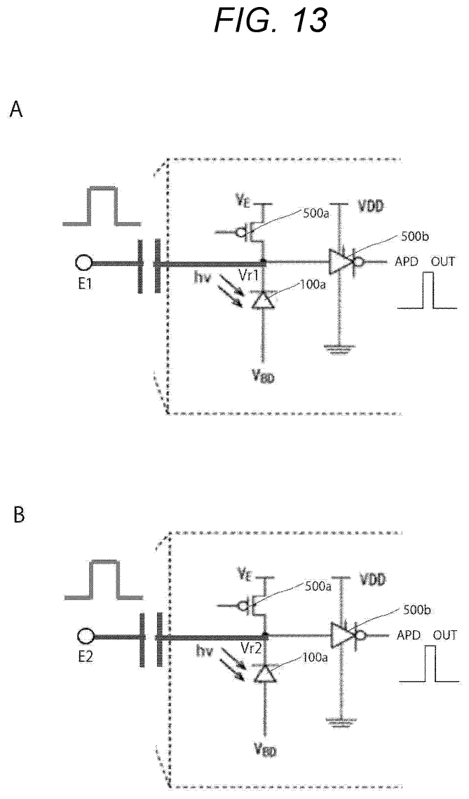

FIG. 12 is a diagram illustrating a planar configuration example of a conductive layer 200c of a photodetection device 60 according to a sixth embodiment of the present technology. FIG. 13A is a diagram illustrating a circuit configuration example 1 of each pixel of the photodetection device 60, and FIG. 13B is a diagram illustrating a circuit configuration example 2 of each pixel of the photodetection device 60.

In the photodetection device 60, a plurality of first pixels 100A1 including a photoelectric conversion element 100a is provided side by side along an in-plane direction of a first semiconductor substrate 100, and the conductive layer 200c has a plurality of electrically separated regions corresponding to different first pixels 100A1 (for example, first and second regions R1 and R2). The photodetection device 60 includes a plurality of dummy pixels 150.

The first region R1 of the conductive layer 200c is provided corresponding to the plurality of first pixels 100A1 and a plurality of dummy pixels 150.

The second region R2 of the conductive layer 200c is provided corresponding to the plurality of first pixels 100A1 and the plurality of dummy pixels 150.

The first and second regions R1 and R2 are connected to different first and second power supplies El and E2, and a recovery potential Vrl is applied to the first region R1 (see FIG. 13A), and a recovery potential Vr2 is applied to the second region R2 (see FIG. 13B). At least one of the first and second power sources El and E2 may be an internal power source or an external power source of a potential application structure PAS. The application timings of the recovery potentials Vrl and Vr2 may be the same or different.

Here, for example, in a case where the first pixel 100A1 corresponding to the first region R1 and the first pixel 100A1 corresponding to the second region R2 are used so that the number of times of driving is different, it is assumed that the fluctuation amount of the breakdown voltage is different.

According to the photodetection device 60, since the recovery potentials Vrl and Vr2 can be individually applied to the first and second regions R1 and R2, it is possible to apply a recovery potential of an appropriate magnitude to each of the first and second regions R1 and R2 even in a case where the first and second regions R1 and R2 are used such that the number of times of driving is different as described above, and eventually, it is possible to sufficiently suppress the characteristic fluctuation of the photoelectric conversion element 100a of each first pixel 100A1. Note that the conductive layer 200c may have three or more electrically separated regions corresponding to different pixels 100A.

### 7. Photodetection Device According to Seventh Embodiment of Present Technology

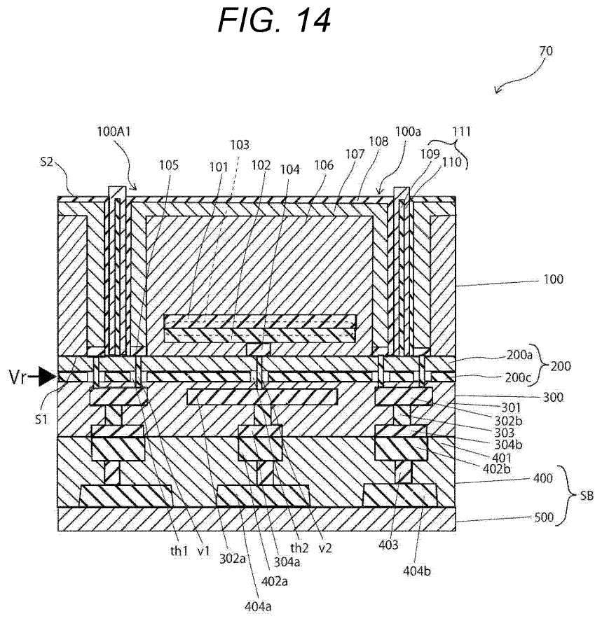

FIG. 14 is a diagram illustrating a cross-sectional configuration example of a first pixel 100A of a photodetection device 70 according to a seventh embodiment of the present technology.

The photodetection device 70 has a substantially similar configuration to the photodetection device 10 according to the first embodiment except that an insulating layer has a single-layer structure including a first insulating layer 200a.

Also in the photodetection device 70, Formula (1) described above is preferably satisfied when the thickness of the first insulating layer 200a as an insulating layer is d. For example, in a case where a desired recovery potential Vr is −20 V, d is preferably set to 25 nm to 100 nm from Formula (1) described above.

According to the photodetection device 70, an effect similar to that of the photodetection device 10 according to the first embodiment can be obtained, and the insulating layer has a single-layer structure, so that the layer configuration can be simplified.

### 8. Photodetection Device According to Eighth Embodiment of Present Technology

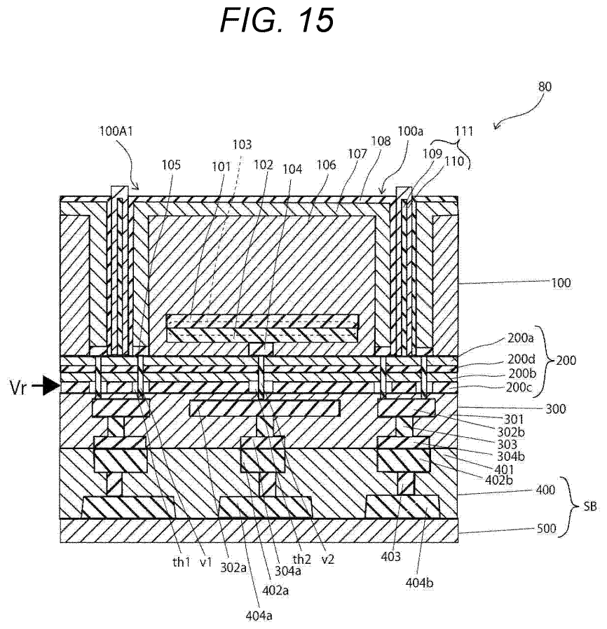

FIG. 15 is a diagram illustrating a cross-sectional configuration example of a first pixel 100A of a photodetection device 80 according to an eighth embodiment of the present technology.

The photodetection device 80 has a configuration similar to the photodetection device 80 according to the fifth embodiment (see FIG. 11) except that a second insulating layer 200b is disposed between a ferroelectric layer 200d and a conductive layer 200c.

According to the photodetection device 80, an effect similar to that of the photodetection device 50 according to the fifth embodiment can be obtained, and a passivation effect by the second insulating layer 200b can be obtained.

### 9. Photodetection Device According to Ninth Embodiment of Present Technology

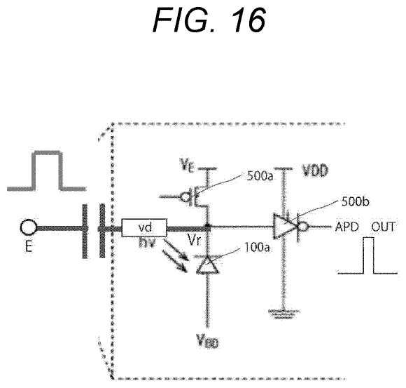

FIG. 16 is a diagram illustrating a circuit configuration example of each pixel of a photodetection device according to a ninth embodiment.

As illustrated in FIG. 16, the photodetection device according to the ninth embodiment has a configuration similar to the photodetection device 10 according to the first embodiment except that a potential application structure PAS includes a voltage divider vd that makes the magnitude of a recovery potential Vr variable.

According to the photodetection device according to the ninth embodiment, since the magnitude of the recovery potential Vr is variable, the recovery potential Vr can be adjusted according to the fluctuation of the breakdown voltage, and the fluctuation of the breakdown voltage can be reliably suppressed.

### 10. Modification of Present Technology

The configuration of the photodetection device according to each embodiment described above can be appropriately changed.

In the photodetection device according to each of the above embodiments, an avalanche photo diode (APD) may be used instead of the SPAD as the photoelectric conversion element having the avalanche multiplication region. Also in this case, by similarly applying the recovery potential to the conductive layer, it is possible to suppress the fluctuation of the breakdown voltage, and eventually, it is possible to sufficiently suppress the characteristic fluctuation of the photoelectric conversion element. Note that, in a case where the APD is used, a bias voltage having an absolute value less than the absolute value of the breakdown voltage is applied to the APD.

In the photodetection device according to each of the above embodiments, the conductivity types (p-type and n-type, anode and cathode) of the layers constituting the photoelectric conversion element may be exchanged. In this case, in a case where the breakdown voltage V_{BD} of the photoelectric conversion element becomes a positive voltage and |V_{BD} l increases, it is considered that the positive charge h is injected into the anode. If this positive charge h can be removed, the fluctuation of the breakdown voltage V_{BD} can be suppressed. Therefore, by applying a positive potential as a recovery potential to the anode, the positive charge h injected into the anode can be removed, and the fluctuation of the breakdown voltage V_{BD} can be suppressed.

The circuit board SB may include, for example, a memory circuit, an AI circuit, an interface circuit, and the like in addition to the logic circuit. Note that the interface circuit is a circuit that inputs and outputs signals. The AI circuit is a circuit that has a learning function with artificial intelligence (AI). The circuit board SB may have a structure in which a plurality of semiconductor substrates on which circuit elements constituting any of the above circuits are provided is laminated with a wiring layer interposed therebetween.

The photodetection device according to the present technology may include the second pixel 100A2 and a dummy pixel. In this case, the via v3 which is a connection portion between the conductive layer 200c and the multilayer wiring may or may not be provided in the dummy pixel.

The photodetection device according to each of the above embodiments has a structure in which the substrate (pixel substrate including first semiconductor substrate 100, laminated structure 200, and first wiring layer 300) on which the pixels are provided and the circuit board SB on which the circuit element is provided are laminated. However, for example, the photodetection device may have a structure in which the pixel and the circuit element are provided side by side in the in-plane direction on the same substrate.

The photodetection device according to each of the above embodiments may include a microlens array including microlenses for each pixel 100A on the second surface S2 side (light incident surface side) of the first semiconductor substrate 100 in a case where the photodetection device is used for sensing such as distance measurement or monochrome imaging.

In a case of being used for color imaging, the photodetection device according to each of the above embodiments may have a color filter array including a color filter for each pixel 100A on the second surface S2 side (light incident surface side) of the first semiconductor substrate 100. Furthermore, the photodetection device according to each of the above embodiments may have a microlens array including microlenses for each pixel 100A on the color filter array.

In the photodetection device according to each of the above embodiments, the first wiring layer 300 and the second wiring layer 400 are electrically connected by, for example, metal bonding, but in addition to or instead of this, they may be electrically connected by, for example, a through silicon via (TSV).

The photodetection device according to each of the above embodiments is a back surface irradiation type, but may be a front surface irradiation type in which the first wiring layer 300 is provided on the light incident surface side of the first semiconductor substrate 100. In this case, the laminated structure 200 may be disposed on the side of the first semiconductor substrate 100 opposite to the first wiring layer 300 side. Further, the potential application structure PAS may supply a potential to the conductive layer 200c from the side opposite to the first semiconductor substrate 100 side of the laminated structure 200.

The photodetection device according to each of the above embodiments is a laminated photodetection device in which the first semiconductor substrate 100 provided with the photoelectric conversion element 100a and the second semiconductor substrate 500 provided with the logic circuit are laminated, but the present technology is also applicable to a non-laminated photodetection device in which the photoelectric conversion element 100a and the logic circuit are formed on the same semiconductor substrate.

The photodetection device according to each of the above embodiments includes the pixel array, but is not limited thereto, and may include at least one pixel. For example, the present technology is also applicable to a photodetection device having a single pixel.

For example, the configurations of the photodetection devices according to the above embodiments may be combined with each other within a range not technically contradictory.

The numerical values, materials, shapes, and the like used in the description of the above embodiments are merely examples, and are not limited thereto.

### 11. Use Example of Photodetection Device to Which Present Technology is Applied

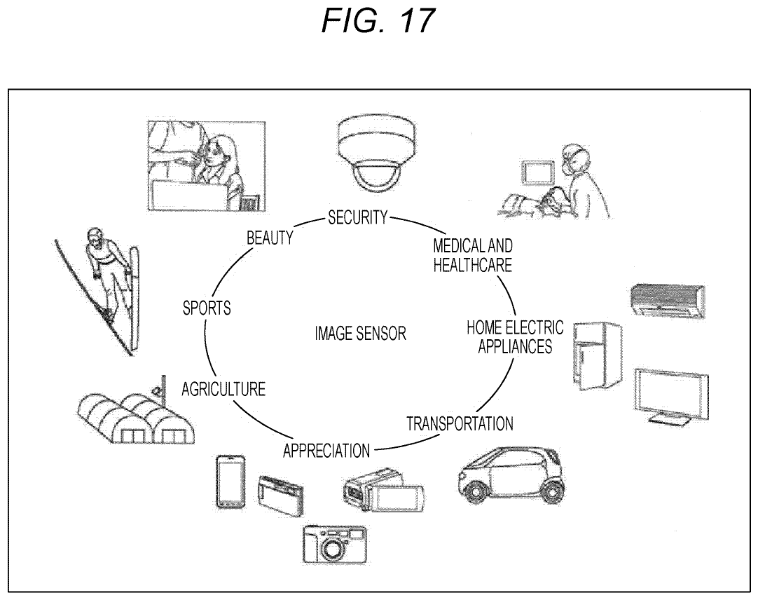

FIG. 17 is a diagram illustrating a usage example in a case where the photodetection device (for example, the photodetection device according to each embodiment) according to the present technology configures a solid-state imaging device (image sensor).

Each of the above-described embodiments can be used, for example, in various cases of sensing light such as visible light, infrared light, ultraviolet light, and X-rays as described below. That is, as illustrated in FIG. 17, for example, the present invention can be used in a device used in a field of appreciation in which an image provided for appreciation is captured, a field of transportation, a field of home electric appliances, a field of medical and healthcare, a field of security, a field of beauty, a field of sports, a field of agriculture, and the like.

Specifically, in the field of appreciation, for example, the photodetection device according to the present technology can be used for a device for capturing an image to be provided for appreciation, such as a digital camera, a smartphone, or a mobile phone with a camera function.

In the field of traffic, for example, the photodetection device according to the present technology can be used for a device used for traffic, such as an in-vehicle sensor that captures images of the front, rear, surroundings, inside, and the like of an automobile, a monitoring camera that monitors traveling vehicles and roads, and a distance measuring sensor that measures a distance between vehicles and the like, for safe driving such as automatic stop, recognition of a driver's condition, and the like.

In the field of home appliances, for example, the photodetection device according to the present technology can be used in a device provided for home appliances such as a television receiver, a refrigerator, and an air conditioner in order to capture an image of a gesture of a user and perform a device operation according to the gesture.

In the field of medical and healthcare, for example, the photodetection device according to the present technology can be used for a device provided for medical and healthcare, such as an endoscope or a device that performs angiography by receiving infrared light.

In the field of security, for example, the photodetection device according to the present technology can be used for a device provided for security, such as a monitoring camera for crime prevention or a camera for person authentication. In the field of beauty, for example, the photodetection device according to the present technology can be used in a device provided for beauty, such as a skin measuring instrument for taking an image of the skin or a microscope for photographing the scalp.

In the field of sports, for example, the photodetection device according to the present technology can be used in a device provided for sports, such as an action camera or a wearable camera for sports or the like.

In the field of agriculture, for example, the photodetection device according to the present technology can be used for a device provided for agriculture, such as a camera for monitoring the condition of fields and crops.

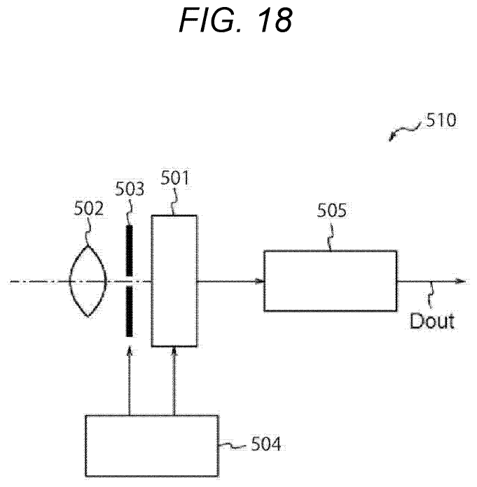

Next, a usage example of the photodetection device (for example, the photodetection device according to each embodiment) according to the present technology will be specifically described. For example, the photodetection device according to each embodiment described above can be applied to any type of electronic device having an imaging function, such as a camera system such as a digital still camera or a video camera, or a mobile phone having an imaging function, as the solid-state imaging device 501. FIG. 18 illustrates a schematic configuration of an electronic device 510 (camera) as an example. The electronic device 510 is a video camera capable of capturing a still image or a moving image, for example, and includes the solid-state imaging device 501, an optical system (optical lens) 502, a shutter device 503, a drive unit 504 that drives the solid-state imaging device 501 and the shutter device 503, and a signal processing unit 505.

The optical system 502 guides image light (incident light) from a subject to a pixel region of the solid-state imaging device 501. The optical system 502 may include a plurality of optical lenses. The shutter device 503 controls a light irradiation period and a light shielding period regarding the solid-state imaging device 501. The drive unit 504 controls a transfer operation of the solid-state imaging device 501 and a shutter operation of the shutter device 503. The signal processing unit 505 performs various types of signal processing on a signal output from the solid-state imaging device 501. A video signal Dout after the signal processing is stored in a storage medium such as a memory or output to a monitor and the like.

### 12. Another Usage Example of Photodetection Device to Which Present Technology is Applied

The photodetection device (for example, the photodetection device according to each embodiment) according to the present technology can also be applied to another electronic device (for example, a distance measuring device) that detects light, such as a time of flight (TOF) sensor. In a case where the photodetection device is applied to a TOF sensor, for example, the photodetection device can be applied to a distance image sensor by a direct TOF measurement method, or a distance image sensor by an indirect TOF measurement method. In the distance image sensor by the direct TOF measurement method, arrival timing of photons is directly obtained in a time domain in each pixel. Therefore, a light pulse having a short pulse width is transmitted, and an electrical pulse is generated by a receiver that responds at a high speed. The present disclosure can be applied to the receiver at that time. In addition, in the indirect TOF method, the flight time of light is measured using a semiconductor element structure in which the detection and accumulation amount of carriers generated by light change depending on the arrival timing of light. The present disclosure can also be applied to such a semiconductor structure. In the case of application to a TOF sensor, it is arbitrary to provide a color filter and a microlens array, and these may not be provided.

### 13. Application Example to Mobile Body

The technology according to the present disclosure (the present technology) can be applied to various products. For example, the technology according to the present disclosure may be realized as any type of moving body such as an automobile, an electric vehicle, a hybrid electric vehicle, a motorcycle, a bicycle, a personal mobility, an airplane, a drone, a ship, or a robot, or as a device mounted on a low power consumption device (for example, a smartphone, a smartwatch, a tablet, eyewear (for example, a head-mounted display), or the like).

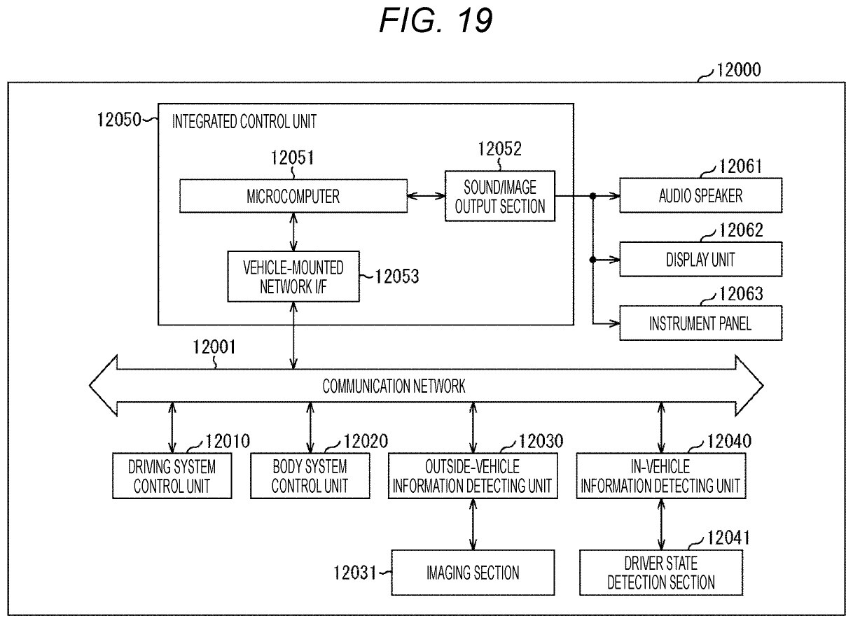

FIG. 19 is a block diagram illustrating a schematic configuration example of a vehicle control system which is an example of a moving body control system to which the technology according to the present disclosure can be applied.

The vehicle control system 12000 includes a plurality of electronic control units connected to each other via a communication network 12001. In the example illustrated in FIG. 19, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as functional components of the integrated control unit 12050.

The drive system control unit 12010 controls the operation of devices related to the drive system of the vehicle in accordance with various programs. For example, the drive system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various lamps such as a headlamp, a back lamp, a brake lamp, a turn indicator, or a fog lamp. In this case, a radio wave transmitted from a portable device that substitutes for a key or signals of various switches may be input to the body system control unit 12020. The body system control unit 12020 receives these input radio waves or signals, and controls a door lock device, the power window device, the lamps, or the like of the vehicle.

The outside-vehicle information detection unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the captured image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light and outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detection unit 12040 detects information about the inside of the vehicle. The in-vehicle information detection unit 12040 is, for example, connected with a driver state detection section 12041 that detects the state of a driver. The driver state detection section 12041, for example, includes a camera that images the driver. On the basis of detection information input from the driver state detection section 12041, the in-vehicle information detection unit 12040 may calculate a degree of fatigue of the driver or a degree of concentration of the driver, or may determine whether or not the driver is dozing.

The microcomputer 12051 can calculate a control target value for the driving force generating device, the steering mechanism, or the braking device on the basis of the information about the inside or outside of the vehicle which information is obtained by the outside-vehicle information detection unit 12030 or the in-vehicle information detection unit 12040, and output a control command to the drive system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

Furthermore, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the surroundings of the vehicle which information is obtained by the outside-vehicle information detection unit 12030 or the in-vehicle information detection unit 12040.

Furthermore, the microcomputer 12051 can output a control command to the body system control unit 12020, on the basis of the information about the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detection unit 12030.

The sound/image output section 12052 transmits an output signal of at least one of a sound and an image to an output device capable of visually or auditorily notifying information to an occupant of the vehicle or the outside of the vehicle. In the example of FIG. 19, as the output device, an audio speaker 12061, a display unit 12062, and an instrument panel 12063 are illustrated. The display section 12062 may, for example, include at least one of an on-board display and a head-up display.

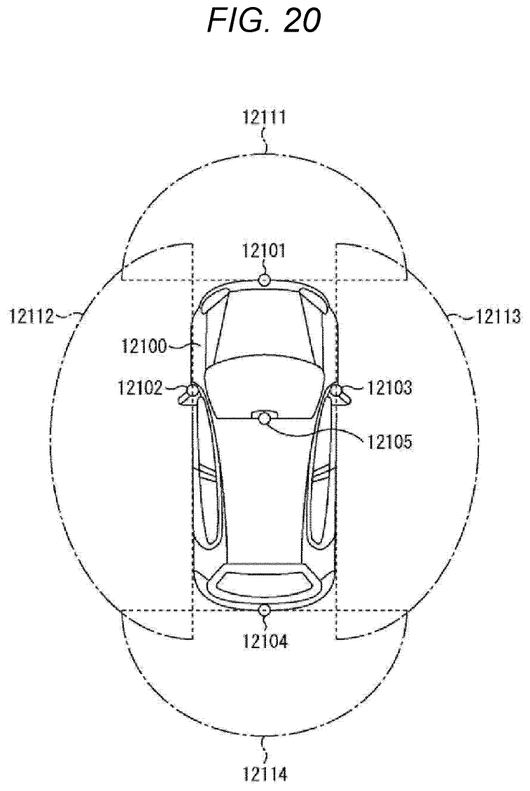

FIG. 20 is a diagram illustrating an example of an installation position of the imaging section 12031.

In FIG. 20, the vehicle 12100 includes imaging sections 12101, 12102, 12103, 12104, and 12105 as the imaging section 12031.

The imaging sections 12101, 12102, 12103, 12104, and 12105 are provided, for example, at positions such as a front nose, a sideview mirror, a rear bumper, a back door, and an upper portion of a windshield in the interior of the vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly images of the sides of the vehicle 12100. The imaging section 12104 provided to the rear bumper or the back door obtains mainly an image of the rear of the vehicle 12100. Images of the front to be obtained by the imaging sections 12101 and 12105 are used mainly to detect a preceding vehicle, a pedestrian, an obstacle, a traffic signal, a traffic sign, a lane, or the like.

Note that FIG. 20 illustrates an example of imaging ranges of the imaging sections 12101 to 12104. An imaging range 12111 represents the imaging range of the imaging section 12101 provided to the front nose, imaging ranges 12112 and 12113 respectively represent the imaging ranges of the imaging sections 12102 and 12103 provided to the sideview mirrors, and an imaging range 12114 represents the imaging range of the imaging section 12104 provided on the rear bumper or the back door. A bird's-eye image of the vehicle 12100 as viewed from above is obtained by superimposing image data captured by the imaging sections 12101 to 12104, for example.

At least one of the imaging sections 12101 to 12104 may have a function of obtaining distance information. For example, at least one of the imaging sections 12101 to 12104 may be a stereo camera including a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and travels in substantially the same direction as the vehicle 12100 at a predetermined speed (for example, equal to or more than 0 km/hour). Moreover, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the drive system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in captured images of the imaging sections 12101 to 12104. Such pedestrian recognition is, for example, performed by a procedure of extracting feature points in the imaged captured by the imaging sections 12101 to 12104 as infrared cameras and a procedure of determining whether or not it is a pedestrian by performing pattern matching processing on a series of feature points representing a contour of an object. When the microcomputer 12051 determines that there is a pedestrian in the taken images of the imaging sections 12101 to 12104 and recognizes the pedestrian, the sound/image output section 12052 controls the display section 12062 so that a rectangular contour for emphasis is displayed in a superimposed manner on the recognized pedestrian. Furthermore, the sound/image output section 12052 may also control the display section 12062 so that an icon or the like representing the pedestrian is displayed at a desired position.

An example of the vehicle control system to which the technology according to the present disclosure (present technology) can be applied has been described above. The technology according to the present disclosure can be applied to the imaging section 12031 and the like, for example, among the components described above. Specifically, the solid-state imaging device 501 of the present disclosure can be applied to the imaging section 12031. By applying the technology according to the present disclosure to the imaging section 12031, it is possible to increase yield and reduce costs related to the manufacturing.

### 14. Application Example to Endoscopic Surgery System

The present technology can be applied to various products. For example, the technology according to the present disclosure (the present technology) may be applied to an endoscopic surgery system.

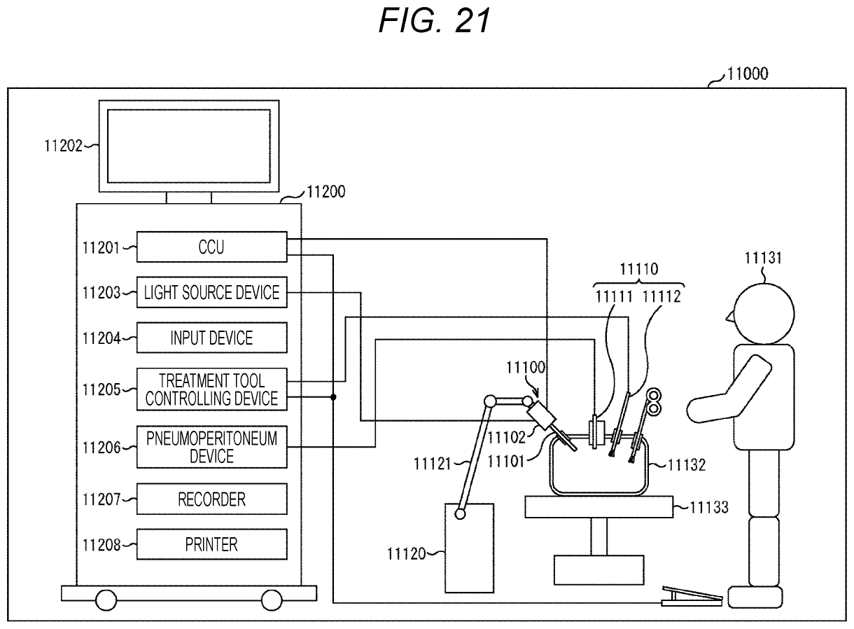

FIG. 21 is a diagram illustrating an example of a schematic configuration of an endoscopic surgery system to which the technology (the present technology) according to the present disclosure can be applied.

FIG. 21 illustrates a state where an operator (doctor) 11131 performs surgery on a patient 11132 on a patient bed 11133, by using an endoscopic surgery system 11000. As illustrated, the endoscopic surgery system 11000 includes an endoscope 11100, other surgical tools 11110 such as a pneumoperitoneum tube 11111 and an energy treatment tool 11112, a supporting arm device 11120 which supports the endoscope 11100 thereon, and a cart 11200 on which various device for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the illustrated example, the endoscope 11100 is illustrated which is included as a rigid endoscope having the lens barrel 11101 of the hard type, but the endoscope 11100 may otherwise be included as a so-called flexible endoscope having a lens barrel of a flexible type.

The lens barrel 11101 has, at a distal end thereof, an opening in which an objective lens is fitted. A light source device 11203 is connected to the endoscope 11100 and light generated by the light source device 11203 is guided to the distal end of the lens barrel by a light guide extending inside the lens barrel 11101, and applied to an observation target in the body cavity of the patient 11132 via the objective lens. Note that, the endoscope 11100 may be a forward-viewing endoscope or may be an oblique-viewing endoscope or a side-viewing endoscope.

An optical system and an imaging element are provided in the inside of the camera head 11102 so that reflected light (observation light) from the observation target is condensed on the imaging element by the optical system. The observation light is photoelectrically converted by the imaging element to generate an electric signal corresponding to the observation light, namely, an image signal corresponding to an observation image. The image signal is transmitted as RAW data to a camera control unit (CCU) 11201.

The CCU 11201 includes a central processing unit (CPU), a graphics processing unit (GPU), or the like and integrally controls operation of the endoscope 11100 and a display device 11202. Moreover, the CCU 11201 receives an image signal from the camera head 11102 and performs, for the image signal, various types of image processing for displaying an image based on the image signal such as, for example, development processing (demosaic processing).

The display device 11202 displays thereon an image based on an image signal, for which the image processing has been performed by the CCU 11201, under the control of the CCU 11201.

The light source apparatus 11203 includes a light source such as a light emitting diode (LED), for example, and supplies irradiation light for imaging a surgical region or the like to the endoscope 11100.

An input device 11204 is an input interface for the endoscopic surgery system 11000. The user may input various types of information and instructions to the endoscopic surgery system 11000 via the input device 11204. For example, the user would input an instruction or a like to change an imaging condition (type of irradiation light, magnification, focal distance or the like) by the endoscope 11100.

A treatment tool controlling device 11205 controls driving of the energy treatment tool 11112 for cautery or incision of a tissue, sealing of a blood vessel, or the like. A pneumoperitoneum device 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is a device capable of recording various types of information relating to surgery. A printer 11208 is a device capable of printing various types of information relating to surgery in various forms such as text, images, and graphs.

Note that, the light source device 11203 which supplies irradiation light when a surgical region is to be imaged to the endoscope 11100 may include a white light source which includes, for example, an LED, a laser light source, or a combination of them. In a case where a white light source includes a combination of red, green, and blue (RGB) laser light sources, since the output intensity and the output timing can be controlled with a high degree of accuracy for each color (each wavelength), adjustment of the white balance of a captured image can be performed by the light source device 11203. Furthermore, in this case, it is also possible to capture an image corresponding to each of RGB in a time division manner by irradiating the observation target with laser light from each of the RGB laser light sources in a time-division manner, and controlling driving of the imaging element of the camera head 11102 in synchronization with the irradiation timing. According to this method, a color image can be obtained even if color filters are not provided for the imaging element.

Furthermore, driving of the light source device 11203 may be controlled so as to change the intensity of output light at every predetermined time interval. By controlling driving of the imaging element of the camera head 11102 in synchronism with the timing of the change of the intensity of light to acquire images time-divisionally and synthesizing the images, an image of a high dynamic range free from underexposed blocked up shadows and overexposed highlights can be generated.

Furthermore, the light source device 11203 may be configured to be able to supply light having a predetermined wavelength band corresponding to special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source device 11203 can be configured to supply such narrow-band light and/or excitation light suitable for special light observation as described above.

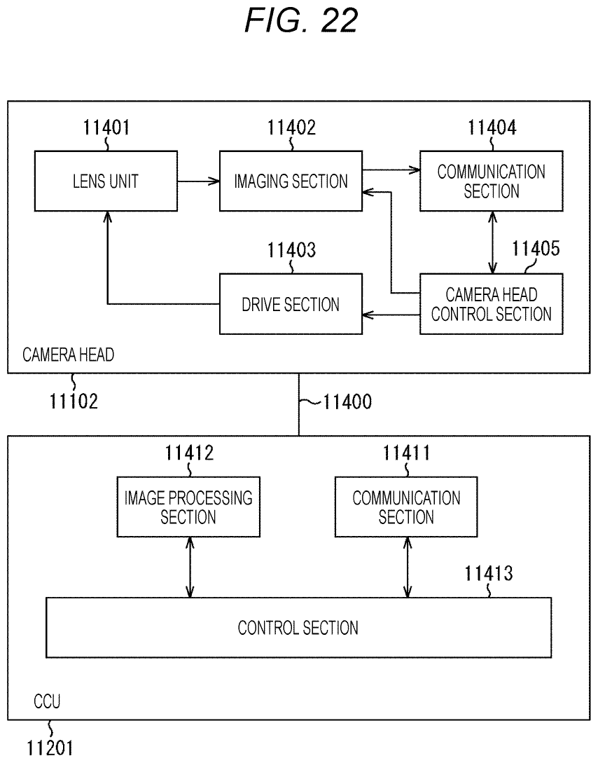

FIG. 22 is a block diagram illustrating an example of a functional configuration of the camera head 11102 and the CCU 11201 illustrated in FIG. 21.

The camera head 11102 includes a lens unit 11401, an imaging section 11402, a drive section 11403, a communication section 11404, and a camera head control section 11405. The CCU 11201 includes a communication section 11411, an image processing section 11412, and a control section 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The image pickup unit 11402 includes an image pickup element. The number of imaging elements which is included by the imaging section 11402 may be one (single-plate type) or a plural number (multi-plate type). In a case where the imaging section 11402 is configured as that of the multi-plate type, for example, image signals corresponding to respective R, G and B are generated by the imaging elements, and the image signals may be synthesized to obtain a color image. Alternatively, the image pickup unit 11402 may include a pair of image pickup elements for acquiring right-eye and left-eye image signals compatible with three-dimensional (3D) display. If 3D display is performed, then the depth of a living body tissue in a surgical region can be grasped more accurately by the surgeon 11131. Note that, in a case where the imaging section 11402 is configured as that of the multi-plate type, a plurality of systems of lens units 11401 may be provided corresponding to the individual imaging elements.

Furthermore, the imaging section 11402 may not necessarily be provided in the camera head 11102. For example, the imaging section 11402 may be provided immediately behind the objective lens in the inside of the lens barrel 11101.

The drive section 11403 includes an actuator and moves the zoom lens and the focusing lens of the lens unit 11401 by a predetermined distance along an optical axis under the control of the camera head control section 11405. Consequently, the magnification and the focal point of a captured image by the imaging section 11402 can be adjusted suitably.

The communication section 11404 includes a communication device for transmitting and receiving various types of information to and from the CCU 11201. The communication section 11404 transmits an image signal acquired from the imaging section 11402 as RAW data to the CCU 11201 via the transmission cable 11400.

Furthermore, the communication section 11404 receives a control signal for controlling driving of the camera head 11102 from the CCU 11201 and supplies the control signal to the camera head control section 11405. The control signal includes information relating to imaging conditions such as, for example, information that a frame rate of a captured image is designated, information that an exposure value upon image picking up is designated, and/or information that a magnification and a focal point of a captured image are designated.

Note that, the imaging conditions such as the frame rate, exposure value, magnification, or focal point may be designated by the user as appropriate or may be set automatically by the control section 11413 of the CCU 11201 on the basis of an acquired image signal. In the latter case, an auto exposure (AE) function, an auto focus (AF) function, and an auto white balance (AWB) function are incorporated in the endoscope 11100.

The camera head control section 11405 controls driving of the camera head 11102 on the basis of a control signal from the CCU 11201 received via the communication section 11404. The communication section 11411 includes a communication device for transmitting and receiving various types of information to and from the camera head 11102. The communication section 11411 receives an image signal transmitted thereto from the camera head 11102 via the transmission cable 11400.

Furthermore, the communication section 11411 transmits a control signal for controlling driving of the camera head 11102 to the camera head 11102. The image signal and the control signal can be transmitted by electrical communication, optical communication, or the like.

The image processing section 11412 performs various types of image processing for an image signal in the form of RAW data transmitted thereto from the camera head 11102.

The control section 11413 performs various control relating to imaging of the surgical site or the like by the endoscope 11100 and display of a captured image obtained by the imaging of the surgical site or the like. For example, the control section 11413 generates a control signal for controlling driving of the camera head 11102.

Furthermore, the control section 11413 controls, on the basis of an image signal for which image process has been performed by the image processing section 11412, the display device 11202 to display a captured image in which the surgical region or the like is imaged. At this time, the control section 11413 may recognize various objects in the captured image using various image recognition technologies. For example, the control section 11413 can recognize a surgical tool such as forceps, a particular living body region, bleeding, mist when the energy treatment tool 11112 is used, and the like by detecting the shape, color, and the like of edges of objects included in a captured image. At the time of causing the display device 11202 to display the captured image, the control section 11413 may display various types of surgery assistance information on the image of the surgical site in a superimposed manner using the recognition result. Where surgery assistance information is displayed in a superimposed manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication, or a composite cable ready for both of electrical and optical communications.

Here, in the illustrated example, communication is performed by wire using the transmission cable 11400, but the communication between the camera head 11102 and the CCU 11201 may be performed wirelessly.

An example of the endoscopic surgery system to which the technology according to the present disclosure can be applied has been described above. The technology according to the present disclosure can be applied to the endoscope 11100, (the imaging section 11402 of) the camera head 11102, and the like among the components described above. Specifically, the solid-state imaging device 111 of the present disclosure can be applied to the imaging section 10402. By applying the technology according to the present disclosure to the endoscope 11100, (the imaging unit 11402 of) the camera head 11102, and the like, it is possible to improve yield and reduce cost related to manufacturing.

Here, the endoscopic surgery system has been described as an example, but the technology according to the present disclosure may be applied to other, for example, a microscopic surgery system or the like.

Furthermore, the present technology may also adopt the following configurations.

(1) A photodetection device according to the present technology includes: a first semiconductor substrate provided with a photoelectric conversion element having an avalanche multiplication region and having first and second surfaces facing each other; a laminated structure disposed on the first surface side and having at least an insulating layer and a conductive layer laminated in this order from a side closer to the first surface; and a potential application structure for applying a potential to the conductive layer.

(2) The photodetection device according to (1), in which the potential application structure includes: a first wiring layer disposed on a side of the laminated structure opposite to the first semiconductor substrate side and electrically connected to the conductive layer; and a circuit board disposed on a side of the first wiring layer opposite to the laminated structure side and electrically connected to the first wiring layer.

(3) The photodetection device according to (2), in which the circuit board includes: a second wiring layer bonded facing the first wiring layer; and a second semiconductor substrate disposed on a side of the second wiring layer opposite to the first wiring layer side and provided with a circuit element.

(4) The photodetection device according to (2) or (3), in which the potential is supplied from the circuit board.

(5) The photodetection device according to any one of (2) to (4), in which an external connection terminal connected to an external power supply that generates the potential is provided on the circuit board.

(6) The photodetection device according to any one of (2) to (5), in which the potential application structure includes at least a via provided in the laminated structure and electrically connecting the conductive layer and the first wiring layer.

(7) The photodetection device according to any one of (2) to (6), in which the first wiring layer and an anode of the photoelectric conversion element are electrically connected via at least a first via provided in the laminated structure, and the first wiring layer and a cathode of the photoelectric conversion element are electrically connected via at least a second via provided in the laminated structure.

(8) The photodetection device according to any one of (2) to (7), in which the conductive layer is provided corresponding to a pixel including at least the photoelectric conversion element, and the via electrically connects a portion of the conductive layer corresponding to the pixel and the first wiring layer.

(9) The photodetection device according to any one of (6) to (8), in which a pixel including the photoelectric conversion element and a dummy pixel not including the photoelectric conversion element are provided side by side along an in-plane direction of the first semiconductor substrate, the conductive layer is provided corresponding to at least the pixel and the dummy pixel, and the via electrically connects a portion of the conductive layer corresponding to the dummy pixel and the first wiring layer.

(10) The photodetection device according to any one of (1) to (9), in which the conductive layer contains at least one selected from polysilicon, W, Ti, Ta, Ni, and Co.

(11) The photodetection device according to any one of (1) to (10), in which the laminated structure includes the insulating layer and the conductive layer alternately laminated in this order from a side close to the first surface.

(12) The photodetection device according to any one of (1) to (11), in which in the laminated structure, at least the insulating layer, a ferroelectric layer, and the conductive layer are laminated in this order from a side closer to the first surface.

(13) The photodetection device according to any one of (1) to (12), in which when the potential is Vr and a thickness of the insulating layer is d, 2M [V/cm]<|Vr|/d<8M [V/cm] holds.

(14) The photodetection device according to any one of (1) to (13), in which when the potential is Vr, a distance between each of an anode electrode and a cathode electrode of the photoelectric conversion element and the conductive layer is equal to or more than |Vr| [V]/1M [V/cm]. (15) The photodetection device according to any one of (1) to (14), in which a plurality of pixels including the photoelectric conversion element is provided along an in-plane direction of the first semiconductor substrate, and the conductive layer is provided corresponding to the plurality of pixels.

(16) The photodetection device according to any one of (1) to (15), in which a plurality of pixels including the photoelectric conversion element is provided along an in-plane direction of the first semiconductor substrate, and the conductive layer has a plurality of regions which is electrically separated and corresponds to different pixels.

(17) The photodetection device according to any one of (1) to (16), in which the potential is generated by a voltage source that applies a voltage to the photoelectric conversion element.

(18) The photodetection device according to any one of (1) to (17), in which the potential application structure includes a voltage divider that makes a magnitude of the potential variable.

(19) The photodetection device according to any one of (1) to (18), in which the photoelectric conversion element includes a p-type semiconductor layer and an n-type semiconductor layer that form the avalanche multiplication region, the n-type semiconductor layer is located on the laminated structure side of the p-type semiconductor layer, and the potential is a negative potential.

(20) The photodetection device according to any one of (1) to (19), in which light is incident from the second surface side of the semiconductor substrate.

(21) An electronic device including the photodetection device according to any one of (1) to (20). (22) A distance measuring device including the photodetection device according to any one of (1) to (20). (23) A solid-state imaging device including the photodetection device according to any one of (1) to (20).

### REFERENCE SIGNS LIST

10, 20, 30, 40, 50, 60, 70, 80 Photodetection device
100 First semiconductor substrate
100A Pixel
100A1 First pixel (pixel)
100A2 Second pixel (pixel)
100a Photoelectric conversion element
101 P-type diffusion layer (p-type semiconductor layer)
102 N-type diffusion layer (n-type semiconductor layer)
103 Avalanche multiplication region
150 Dummy pixel
200 Laminated structure
200a First insulating layer (insulating layer or part thereof)
200b Second insulating layer (part of insulating layer)
200c Conductive layer
200c1 First conductive layer
200c2 Second conductive layer
200d Ferroelectric layer
300 First wiring layer
400 Second wiring layer
500 Second semiconductor substrate
510 Electronic device
PAS Potential application structure
SB Circuit board
S1 First surface
S2 Second surface
v1 First via
v2 Second via
v3 Via
Vr Recovery potential (potential)
R1 First region (region)
R2 Second region (region)

1. A photodetection device comprising:
a first semiconductor substrate provided with a photoelectric conversion element having an avalanche multiplication region and having first and second surfaces facing each other;
a laminated structure disposed on the first surface side and having at least an insulating layer and a conductive layer laminated in this order from a side closer to the first surface;
and a potential application structure for applying a potential to the conductive layer.

2. The photodetection device according to claim 1, wherein
the potential application structure includes:
a first wiring layer disposed on a side of the laminated structure opposite to the first semiconductor substrate side and electrically connected to the conductive layer; and
a circuit board disposed on a side of the first wiring layer opposite to the laminated structure side and electrically connected to the first wiring layer.

3. The photodetection device according to claim 2, wherein
the circuit board includes:
a second wiring layer bonded facing the first wiring layer; and
a second semiconductor substrate disposed on a side of the second wiring layer opposite to the first wiring layer side and provided with a circuit element.

4. The photodetection device according to claim 2, wherein the potential is supplied from the circuit board.

5. The photodetection device according to claim 2, wherein an external connection terminal connected to an external power supply that generates the potential is provided on the circuit board.

6. The photodetection device according to claim 2, wherein the potential application structure includes at least a via provided in the laminated structure and electrically connecting the conductive layer and the first wiring layer.

7. The photodetection device according to claim 6, wherein
the first wiring layer and an anode of the photoelectric conversion element are electrically connected via at least a first via provided in the laminated structure, and
the first wiring layer and a cathode of the photoelectric conversion element are electrically connected via at least a second via provided in the laminated structure.

8. The photodetection device according to claim 6, wherein
the conductive layer is provided corresponding to a pixel including at least the photoelectric conversion element, and
the via electrically connects a portion of the conductive layer corresponding to the pixel and the first wiring layer.

9. The photodetection device according to claim 6, wherein
a pixel including the photoelectric conversion element and a dummy pixel not including the photoelectric conversion element are provided side by side along an in-plane direction of the first semiconductor substrate,
the conductive layer is provided corresponding to at least the pixel and the dummy pixel, and
the via electrically connects a portion of the conductive layer corresponding to the dummy pixel and the first wiring layer.

10. The photodetection device according to claim 1, wherein the conductive layer contains at least one selected from polysilicon, W, Ti, Ta, Ni, and Co.

11. The photodetection device according to claim 1, wherein the laminated structure has a floating gate structure in which the insulating layer and the conductive layer are alternately laminated in this order from a side close to the first surface.

12. The photodetection device according to claim 1, wherein in the laminated structure, at least the insulating layer, a ferroelectric layer, and the conductive layer are laminated in this order from a side closer to the first surface.

13. The photodetection device according to claim 1, wherein
when the potential is Vr and a thickness of the insulating layer is d,
2M [V/cm]<|Vr|/d<8M [V/cm]
holds.

14. The photodetection device according to claim 1, wherein
when the potential is Vr,
a distance between each of an anode electrode and a cathode electrode of the photoelectric conversion element and the conductive layer is equal to or more than |Vr|[V]/1M [V/cm].

15. The photodetection device according to claim 1, wherein
a plurality of pixels including the photoelectric conversion element is provided along an in-plane direction of the first semiconductor substrate, and
the conductive layer is provided corresponding to the plurality of pixels.

16. The photodetection device according to claim 1, wherein
a plurality of pixels including the photoelectric conversion element is provided along an in-plane direction of the first semiconductor substrate, and
the conductive layer has a plurality of regions which is electrically separated and corresponds to different pixels.

17. The photodetection device according to claim 1, wherein the potential is generated by a voltage source that applies a voltage to the photoelectric conversion element.

18. The photodetection device according to claim 1, wherein the potential application structure includes a voltage divider that makes a magnitude of the potential variable.

19. The photodetection device according to claim 1, wherein
the photoelectric conversion element includes a p-type semiconductor layer and an n-type semiconductor layer that form the avalanche multiplication region,
the n-type semiconductor layer is located on the laminated structure side of the p-type semiconductor layer, and
the potential is a negative potential.

20. The photodetection device according to claim 1, wherein light is incident from the second surface side of the first semiconductor substrate.
